(19) United States
(12) Patent Application Publication
(10) Pub. No.: US 2025/0080063 A1
(43) Pub. Date: Mar. 6, 2025

(54) TRANSISTOR WITH GATE LAYOUT, DEVICE IMPLEMENTING THE TRANSISTOR WITH OUTPUT PRE-MATCHING, AND PROCESS OF IMPLEMENTING THE SAME

(71) Applicant: WOLFSPEED, INC., Durham, NC (US)

(72) Inventors: Jonathan CHANG, Durham, NC (US); Qianli MU, Durham, NC (US); Marvin MARBELL, Cary, NC (US); Zulhazmi MOKHTI, Durham, NC (US)

(21) Appl. No.: 18/461,980

(22) Filed: Sep. 6, 2023

(51) Int. Cl. H03F 3/195; H01L 23/66; H01L 29/778; H03F 1/02; H03F 1/56

(52) U.S. Cl. CPC H03F 3/195; H01L 23/66; H03F 1/0288; H03F 1/565; H10D 30/475; H01L 2223/6672; H03F 2200/451

(57) ABSTRACT

A device may include at least one drain pad arranged at a first die side of the transistor die and/or at a second die side of the transistor die, the first die side and the second die side being opposed sides of the transistor die. Also, the device may include drain fingers configured to extend from the at least one drain pad longitudinally toward a central location of the transistor die. Furthermore, the device may include source fingers configured to extend from the at least one drain pad longitudinally toward the central location of the transistor die. In addition, the device may include a gate pad and a gate and the gate is configured to extend along implementations of the drain fingers and/or the source fingers. Moreover, the device may include where the gate pad is arranged on an axis at least semi-orthogonally to an axis of the at least one drain pad.

### FIELD OF THE DISCLOSURE

The disclosure relates to a transistor with a gate layout, a device implementing the transistor with output pre-matching, a process of implementing the transistor, and a process of implementing the device.

### BACKGROUND OF THE DISCLOSURE

For various RF (radiofrequency) power amplifiers there is a growing demand for improving broadband and efficiency. However, typical RF devices implement gate, source, and drain configurations that provide limitations in improving broadband and efficiency.

Accordingly, there is a need for RF devices for improving broadband and efficiency.

### SUMMARY OF THE DISCLOSURE

In one general aspect, a transistor may include at least one drain pad arranged at a first die side of the transistor die and/or at a second die side of the transistor die, the first die side and the second die side being opposed sides of the transistor die. Transistor may also include drain fingers configured to extend from the at least one drain pad longitudinally toward a central location of the transistor die. Transistor may furthermore include source fingers configured to extend from the at least one drain pad longitudinally toward the central location of the transistor die. Transistor may in addition include a gate pad and a gate and the gate is configured to extend along implementations of the drain fingers and/or the source fingers. Transistor may moreover include where the gate pad is arranged on an axis at least semi-orthogonally to an axis of the at least one drain pad.

In one general aspect, a transistor may include drain pads arranged at a first die side of the transistor die and at a second die side of the transistor die, the first die side and the second die side being opposed sides of the transistor die. Transistor may also include drain fingers arranged at the first die side of the transistor die and the second die side of the transistor die. Transistor may furthermore include source fingers arranged at the first die side of the transistor die and a second die side of the transistor die. Transistor may in addition include a gate pad and a gate and the gate configured to extend along implementations of the drain fingers and/or the source fingers on the first die side and implementations of the drain fingers and/or the source fingers on the second die side.

In one general aspect, a process may include arranging at least one drain pad at a first die side of the transistor die and/or at a second die side of the transistor die, the first die side and the second die side being opposed sides of the transistor die. Process may also include configuring drain fingers to extend from the at least one drain pad longitudinally toward a central location of the transistor die. Process may furthermore include configuring source fingers to extend from the at least one drain pad longitudinally toward the central location of the transistor die. Process may in addition include arranging a gate pad on an axis at least semi-orthogonally to an axis of the at least one drain pad. Process may moreover include configuring a gate to extend along implementations of the drain fingers and/or the source fingers.

In one general aspect, a process may include arranging drain pads at a first die side of the transistor die and at a second die side of the transistor die, the first die side and the second die side being opposed sides of the transistor die. Process may also include arranging drain fingers at the first die side of the transistor die and the second die side of the transistor die. Process may furthermore include arranging source fingers at the first die side of the transistor die and a second die side of the transistor die. Process may in addition include providing a gate pad. Process may moreover include configuring a gate to extend along implementations of the drain fingers and/or the source fingers on the first die side and implementations of the drain fingers and/or the source fingers on the second die side.

There has thus been outlined, rather broadly, certain aspects of the disclosure in order that the detailed description thereof herein may be better understood, and in order that the present contribution to the art may be better appreciated. There are, of course, additional aspects of the disclosure that will be described below and which will form the subject matter of the claims appended hereto.

In this respect, before explaining at least one aspect of the disclosure in detail, it is to be understood that the disclosure is not limited in its application to the details of construction and to the arrangements of the components set forth in the following description or illustrated in the drawings. The disclosure is capable of aspects in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the disclosure. It is important, therefore, that the claims be regarded as including such equivalent constructions insofar as they do not depart from the spirit and scope of the disclosure.

### BRIEF DESCRIPTION OF THE DRAWINGS

FIG. 1 illustrates a plan view of a transistor die according to aspects of the disclosure.

FIG. 2 illustrates a perspective view of the transistor die according to FIG. 2.

FIG. 3 illustrates a schematic of a device according to aspects of the disclosure.

FIG. 4 illustrates a plan view of a device according to aspects of the disclosure.

FIG. 5 illustrates a plan view of another implementation of the transistor die according to aspects of the disclosure.

FIG. 6 illustrates a plan view of another transistor die according to aspects of the disclosure.

FIG. 7 illustrates a plan view of another transistor die according to aspects of the disclosure.

FIG. 8 illustrates a schematic of a device according to aspects of the disclosure.

FIG. 9 illustrates a plan view of another transistor die according to aspects of the disclosure.

FIG. 10 illustrates a plan view of another transistor die according to aspects of the disclosure.

FIG. 11 is a schematic cross-sectional view of the transistor die, the device, and the integrated passive device (IPD) according to aspects of the disclosure.

FIG. 12 is a schematic cross-sectional view of the transistor die according to aspects of the disclosure.

FIG. 13 illustrates an exemplary process of implementing a transistor die, a device, and/or an integrated passive device (IPD).

### DETAILED DESCRIPTION

The disclosure will now be described with reference to the drawing figures, in which like reference numerals refer to like parts throughout. Aspects of the disclosure advantageously provide a transistor with a gate layout, a device implementing the transistor with output pre-matching, a process of implementing the transistor, and a process of implementing the device.

The disclosure relates to a transistor with a gate layout, a device implementing the transistor with output pre-matching, a process of implementing the transistor, and a process of implementing the device. In particular, the disclosure relates to a semi-orthogonal or orthogonal gate layout of a transistor. In aspects, the disclosure relates a semi-orthogonal or orthogonal gate layout of a field effect transistor. In aspects, the disclosure relates a semi-orthogonal or orthogonal gate layout of a high-electron-mobility transistor (HEMT). In aspects, the disclosure relates to a semi-orthogonal or orthogonal gate layout of a flip-chip field effect transistor. In aspects, the disclosure relates to a semi-orthogonal or orthogonal gate layout of a flip-chip a high-electron-mobility transistor (HEMT). Further, the disclosure relates to a device implementing such a transistor together with an implementation of output pre-matching.

The disclosed device can be used in RF power products for base stations, such as 4G base stations, 5G base station, and/or the like. For base station applications, such as 4G base station applications, 5G base station applications, and/or the like there has been a growing demand for broadband and high-efficiency RF (radio frequency) power amplifiers. The disclosed device provides a solution to obtain greater broadband and higher efficiency.

In aspects of the disclosure, the device may implement a die that has a semi-orthogonal gate layout and/or an orthogonal gate layout to a RF path. Further, in aspects of the device, the die may implement drain pads (also can be the gate pad) on both sides of the die. Additionally, a configuration of the device and the die are configured to be flexible for the output pre-matching.

In aspects, the device may implement the die with flip-chip technology. Accordingly, implementations of the device as described herein together with the flip-chip technology, may result in a capacitance of the pads being lower, which is beneficial for broadband designs and/or implementations. Further, the device may be configured such that a coupling of the RF path and shunt L circuits is lower, which helps to implement higher efficiency.

In aspects, the device may be implemented such that DC is feed through the shunt L circuit, a series capacitor may be arranged on the die, together with a microstrip line to implement a series LC resonator, which can compensate for an impedance change over frequency from a shunt L matching network. This configuration may further improve the bandwidth.

In aspects, the device may implement a split finger structure. Moreover, the device may implement an output match in X and Y directions, which may be flexible for a design and/or implementation. Further, the device may be configured such that DC may be fed through the shunt L circuits, which can be integrated in the series capacitor on the die, to obtain wider bandwidth. Additionally, the device may be configured such that there is lower coupling between a tuning wire and a drain wire, when bonding wires are used, which can further improve the efficiency.

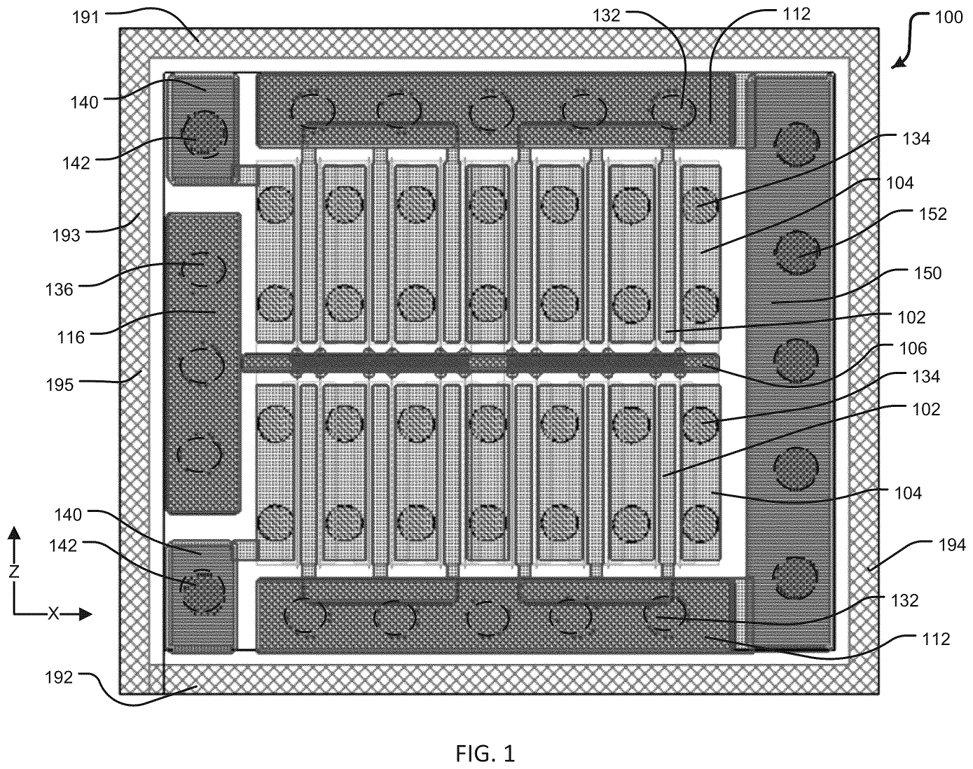

FIG. 1 illustrates a plan view of a transistor die according to aspects of the disclosure.

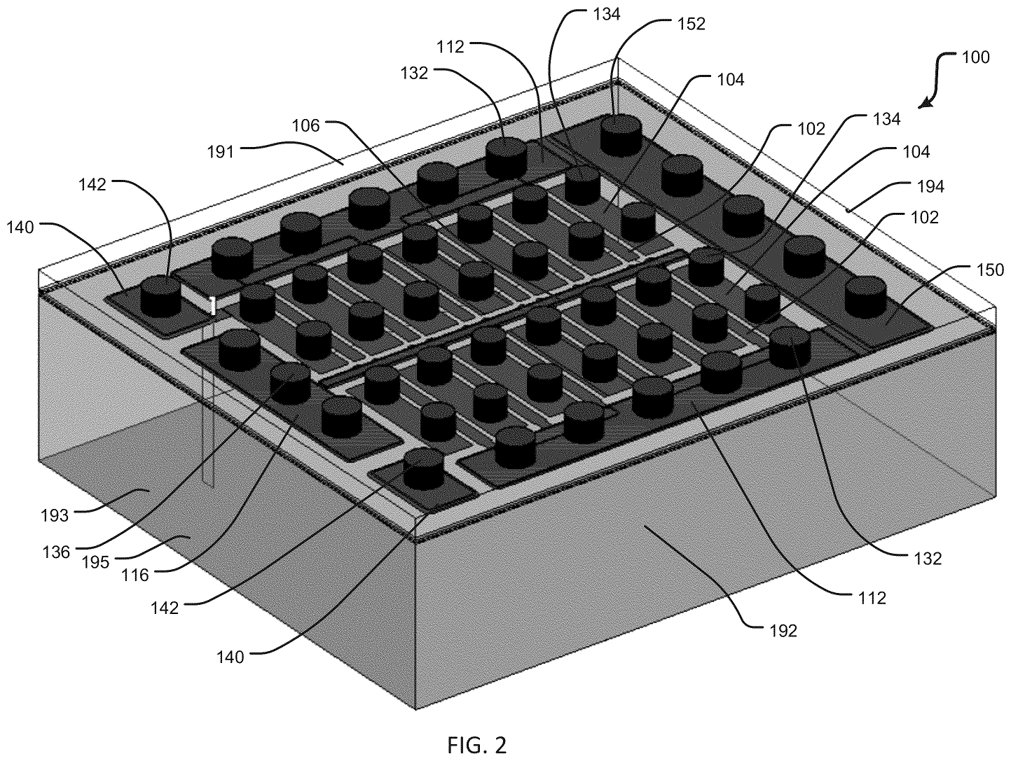

FIG. 2 illustrates a perspective view of the transistor die according to FIG. 2.

In particular, FIG. 1 illustrates a plan view of a transistor die 100 according to aspects of the disclosure. The transistor die 100 illustrated in FIG. 1 and described herewith may optionally include any other features of the transistor die 100 described in any of the other figures. Moreover, any of the other implementations in the transistor die 100 described herein may be implemented in the transistor die 100 illustrated in FIG. 1.

The transistor die 100 may include drain pads 112 arranged at a first die side 191 of the transistor die 100 and at a second die side 192 of the transistor die 100. In particular, the first die side 191 and the second die side 192 may be arranged on opposite sides of the transistor die 100 along a z axis as illustrated in FIG. 1.

Additionally, the drain pads 112 may extend on the transistor die 100 from a third side 193 to a fourth side 194 of the transistor die 100. In particular, the third side 193 and the fourth side 194 may be arranged on opposite sides of the transistor die 100 along an x axis as illustrated in FIG. 1.

The drain pads 112 may have a dimension along the X axis and/or extending laterally across the transistor die 100 greater than a dimension along the Z axis and/or longitudinally along the transistor die 100. In aspects, a longer dimension of the drain pads 112 may extend along the X axis and/or extend laterally across the transistor die 100.

The drain pads 112 may be connected to drain fingers 102 arranged at the first die side 191 of the transistor die 100 and the second die side 192 of the transistor die 100. The drain fingers 102 may extend from the drain pads 112 along the z axis and/or longitudinally toward a central location 195 of the transistor die 100. Further, the drain fingers 102 may include multiple parallel implementations extending along the X axis of the transistor die 100 and/or extending laterally across the transistor die 100. Accordingly, there may be multiple parallel implementations of the drain fingers 102 extending along the X axis of the transistor die 100 and/or extending laterally across the transistor die 100 on the first die side 191; and there may be multiple implementations of the drain fingers 102 extending along the X axis of the transistor die 100 and/or extending laterally across the transistor die 100 on the second die side 192.

The drain fingers 102 may have a dimension along the Z axis and/or longitudinally along the transistor die 100 greater than a dimension along the X axis and/or extending laterally across the transistor die 100. In aspects, a longer dimension of the drain fingers 102 may extend along the Z axis and/or extend longitudinally along the transistor die 100.

Additionally, the transistor die 100 may include source fingers 104. In particular, implementations of the source fingers 104 may be arranged at the first die side 191 of the transistor die 100 and implementations of the source fingers 104 may be arranged at a second die side 192 of the transistor die 100.

Further, the source fingers 104 may include multiple parallel implementations extending along the X axis of the transistor die 100 and/or extending laterally across the transistor die 100. In aspects, there may be implementations of the source fingers 104 adjacent each implementation of the drain pads 112. Accordingly, there may be multiple implementations of the source fingers 104 extending along the X axis of the transistor die 100 and/or extending laterally across the transistor die 100 on the first die side 191; and there may be multiple implementations of the source fingers 104 extending along the X axis of the transistor die 100 and/or extending laterally across the transistor die 100 on the second die side 192.

The source fingers 104 may have a dimension along the Z axis and/or longitudinally along the transistor die 100 greater than a dimension along the X axis and/or extending laterally across the transistor die 100. In aspects, a longer dimension of the source fingers 104 may extend along the Z axis and/or extend longitudinally along the transistor die 100.

Accordingly, the transistor die 100 may implement a structure that includes multiple parallel implementations of the drain fingers 102 and the source fingers 104 on the first die side 191 and multiple parallel implementations of the drain fingers 102 and the source fingers 104 on the second die side 192. Further, the transistor die 100 may implement multiple implementations of the drain pads 112 with at least one implementation of the drain pads 112 on the first die side 191 and at least one implementation of the drain pads 112 on the second die side 192. Additionally, the multiple implementations of the drain fingers 102 and the source fingers 104 may be arranged between the multiple implementations of the drain pads 112.

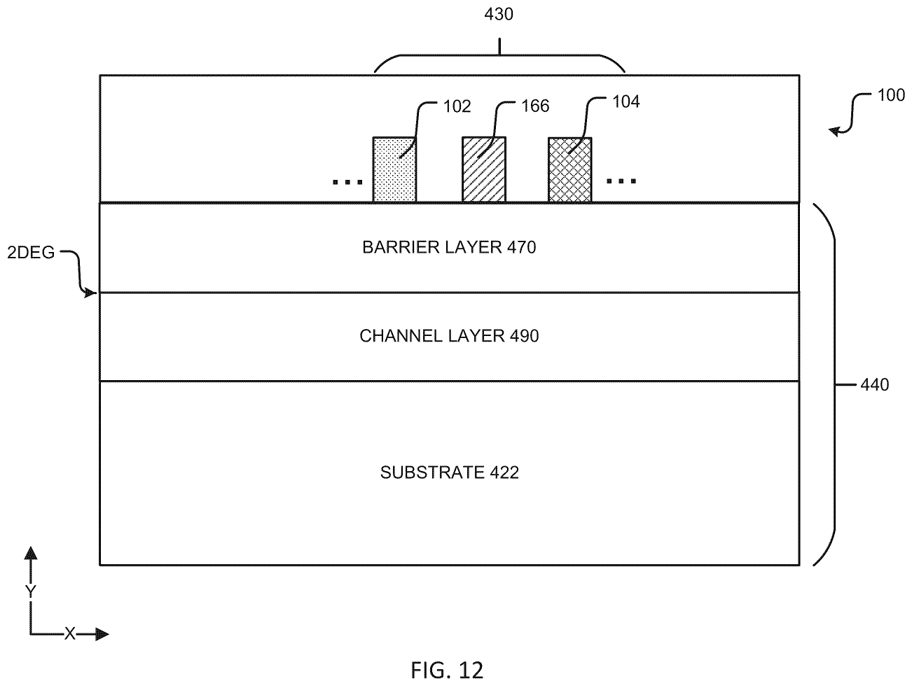

Further, the transistor die 100 may include a gate pad 116 that may extend along implementations of the drain fingers 102 and/or the source fingers 104 on the first die side 191 and implementations of the drain fingers 102 and/or the source fingers 104 on the second die side 192. In aspects, the gate pad 116 may extend along the Z axis and/or extending longitudinally along the transistor die 100 in the central location 195 of the transistor die 100. Further, the gate pad 116 may connect to a gate bus 106 that may include gate fingers 166 (illustrated in FIG. 12) extending along the z axis between implementations of the drain fingers 102 and the source fingers 104.

The gate pad 116 may have a dimension along the Z axis and/or longitudinally along the transistor die 100 greater than a dimension along the X axis and/or extending laterally across the transistor die 100. In aspects, a longer dimension of the gate pad 116 may extend along the Z axis and/or extend longitudinally along the transistor die 100.

In aspects, there may be an implementation of the drain fingers 102 between and/or adjacent two implementations of the source fingers 104. In aspects, there may be implementations of the source fingers 104 on either side of the drain fingers 102.

In aspects, the source fingers 104 and/or the drain fingers 102 may be arranged between implementations of the drain pads 112. In aspects, an implementation of the drain pads 112 may be arranged closer to the first die side 191 than the source fingers 104 and/or the drain fingers 102. In aspects, an implementation of the drain pads 112 may be arranged closer to the second die side 192 than the source fingers 104 and/or the drain fingers 102.

In aspects, the source fingers 104 and/or the drain fingers 102 may be arranged closer to the central location 195 than the implementations of the drain pads 112. In aspects, the gate pad 116 may be arranged closer to the third side 193 than the source fingers 104 and/or the drain fingers 102.

In aspects, the gate pad 116 may be configured to receive an input from the third side 193. In aspects, an implementation of the drain pads 112 may be configured to output toward the first die side 191; and an implementation of the drain pads 112 may be configured to output toward the second die side 192.

In aspects, the gate pad 116 may extend along the z-axis of the transistor die 100 and/or longitudinally along the transistor die 100; and the implementations of the drain pads 112 may extend along the X axis of the transistor die 100 and/or laterally across the transistor die 100. Accordingly, the gate pad 116 may be arranged on an axis at least semi-orthogonally and/or orthogonally to an axis of the implementations of the drain pads 112. Accordingly, an input to the gate pad 116 may be arranged on an axis at least semi-orthogonally and/or orthogonally to an axis of an output of the implementations of the drain pads 112.

In this regard, orthogonal or orthogonally being defined as 90° or perpendicular. Accordingly, an axis orthogonal to another axis may be at 90° or perpendicular. In other words, a first axis being orthogonal or perpendicular to a second axis means that the first axis is at 90° or perpendicular to the second axis. In aspects, a first axis being orthogonal or perpendicular to a second axis means that the first axis is at 90° or perpendicular to the second axis within variances of manufacturing of the transistor die 100.

Further, “semi-orthogonally” as used herein may be defined as being within 0°-40°, 0°-30°, 0°-20°, 0°-10°, or 0°-5° of orthogonal or perpendicular. In other words, a first axis being semi-orthogonal to a second axis means that the first axis is at 90° or perpendicular within 0°-40°, 0°-30°, 0°-20°, 0°-10°, or 0°-5°.

In aspects, a longer dimension of the gate pad 116 may extend along the z-axis of the transistor die 100 and/or longitudinally along the transistor die 100; and a longer dimension of the implementations of the drain pads 112 may extend along the X axis of the transistor die 100 and/or laterally across the transistor die 100. Accordingly, a longer dimension of the gate pad 116 may be arranged on an axis at least semi-orthogonally and/or orthogonally to a longer dimension of an axis of the implementations of the drain pads 112.

In aspects, the transistor die 100 may implement the gate pad 116 along and adjacent the third side 193. Accordingly, the gate pad 116 may have a longitudinal axis parallel or semi-parallel to the z axis.

Further, an output from the transistor die 100 from the drain pads 112 may be along the z-axis. Accordingly, the output from the transistor die 100 from the drain pads 112 may be arranged on an axis at least semi-orthogonally and/or orthogonally to an axis of the input to the gate pad 116. Accordingly, an input to the gate pad 116 may be arranged on an axis at least semi-orthogonally and/or orthogonally to an axis of an output of the implementations of the drain pads 112.

In alternative implementations of the transistor die 100, the arrangement of the drain pads 112 and the gate pad 116 may be reversed. In this regard, the FIG. 1 implementation of the transistor die 100 may implement the drain pads 112 on both sides of the transistor die 100 and the gate pad 116 on another side of the transistor die 100. In alternative implementations of the transistor die 100, the transistor die 100 may implement the gate pad 116 on both sides of the transistor die 100 and the drain pads 112 on another side of the transistor die 100. In this regard, this alternative implementation of the transistor die 100 may include two implementations of the gate pad 116 and a single patient of the drain pads 112. In aspects, the transistor die 100 may be implemented with flip chip technology such that the view of the transistor die 100 illustrated in FIG. 1 may be a bottom side view of the transistor die 100 after the transistor die 100 is flipped and implemented in a device 200 as further described herein.

Additionally, the transistor die 100 may include electrical connections extending from various portions thereof for connection to the device 200.

In aspects, the transistor die 100 may include a drain pad connection 132 arranged on the drain pads 112. In aspects, the drain pad connection 132 may connect the drain pads 112 to the device 200. In aspects, the drain pad connection 132 may be a pillar, a Copper pillar, and/or the like. In aspects, there may be multiple implementations of the drain pad connection 132 on the drain pads 112 extending along the X axis and/or extending laterally across the transistor die 100.

In aspects, the transistor die 100 may include a source connection 134 arranged on the source fingers 104. In aspects, the source connection 134 may connect the source fingers 104 to the device 200. In aspects, the source connection 134 may be a pillar, a Copper pillar, and/or the like. In aspects, there may be multiple implementations of the source connection 134 on each implementation of the source fingers 104 extending along the z axis. Accordingly, there may be multiple implementations on the source connection 134 extending across the X axis and/or extending laterally across the transistor die 100 from the multiple parallel implementations of the source fingers 104.

In aspects, the transistor die 100 may include a gate pad connection 136 arranged on the gate pad 116. In aspects, the gate pad connection 136 may connect the gate pad 116 to the device 200. In aspects, the gate pad connection 136 may be a pillar, a Copper pillar, and/or the like. In aspects, there may be multiple implementations of the gate pad connection 136 on the gate pad 116 extending along the z axis and/or extending longitudinally along the transistor die 100.

Further, the gate pad 116 may connect to a gate bus 106 that may include gate fingers 166 (illustrated in FIG. 12) extending along the z axis between implementations of the drain fingers 102 and the source fingers 104.

In aspects, there may be implementations of the drain fingers 102 and the source fingers 104 between the gate bus 106 and the drain pads 112 on the first die side 191; and there may be implementations of the drain fingers 102 and the source fingers 104 between the gate bus 106 and the drain pads 112 on the second die side 192.

As further illustrated in FIG. 1, the transistor die 100 may include a second harmonic control capacitor 140. One implementation of the second harmonic control capacitor 140 may be arranged adjacent the first die side 191 and/or the third side 193 and another implementation of the second harmonic control capacitor 140 may be arranged adjacent the second die side 192 and/or the third side 193. In aspects, an implementation of the second harmonic control capacitor 140 may be connected to the source fingers 104 arranged on the first die side 191; and an implementation of the second harmonic control capacitor 140 may be connected to the source fingers 104 arranged on the second die side 192. Further, the source fingers 104 may be electrically connected to ground.

In aspects, the second harmonic control capacitor 140 may include a second harmonic circuit connection 142. In aspects, the second harmonic circuit connection 142 may connect the second harmonic control capacitor 140 and/or the source fingers 104 to the device 200. In aspects, the second harmonic circuit connection 142 may be a pillar, a Copper pillar, and/or the like.

Further, the second harmonic control capacitor 140 may be implemented with a metal insulator metal (MIM) configuration. In this regard, a first metal of the second harmonic control capacitor 140 may be arranged on the transistor die 100, an insulator material may be arranged on the first metal, and a second metal may be arranged on the insulator material.

As further illustrated in FIG. 1, the transistor die 100 may include an output capacitor 150. The output capacitor 150 may be configured as an output series capacitor. In aspects, the output capacitor 150 may be arranged adjacent the fourth side 194 and may extend along the z-axis from the first die side 191 to the second die side 192. In aspects, the output capacitor 150 may connect to the implementation of the drain pads 112 implemented along the first die side 191; and the output capacitor 150 may connect to the implementation of the drain pads 112 implemented along the second die side 192.

In aspects, the output capacitor 150 may include a capacitor connection 152. In aspects, the capacitor connection 152 may connect the output capacitor 150 to the device 200. In aspects, the capacitor connection 152 may be a pillar, a Copper pillar, and/or the like.

Further, the output capacitor 150 may be implemented with a metal insulator metal (MIM) configuration. In this regard, a first metal of the output capacitor 150 may be arranged on the transistor die 100, an insulator material may be arranged on the first metal, and a second metal may be arranged on the insulator material.

In aspects, the transistor die 100 may include Aluminum indium gallium nitride. Aluminum indium gallium nitride (often written as AlₓIn_{y}Ga_{z}N where 0≤x≤1, 0≤y≤1, 0≤z≤1, and x+y+z=1, or (AlInGa)N or AlInGaN or sometimes simply GaN) is an alloy that is increasingly used for power switching, amplification and other applications. Given the material properties of AllnGaN, semiconductor devices made from this material can operate at higher voltages, higher temperatures, higher switching frequencies, with lower on resistance and ultimately achieving greater system efficiencies, e.g., when compared to existing Si devices. These properties can enable significantly reduced system volume due to decreased cooling requirements and smaller passive components, thus contributing to overall lower system costs, e.g. when compared to silicon. Power devices made from GaN and its alloys show great promise for applications including power conversion, power control, power conditioning, power switching, or power management. In particular, power supplies, motor drives, photovoltaic inverters, UPS inverters, EV chargers and EV/HEC converter/inverter/drives will benefit from the improved efficiency, speed and size of “GaN Power” devices.

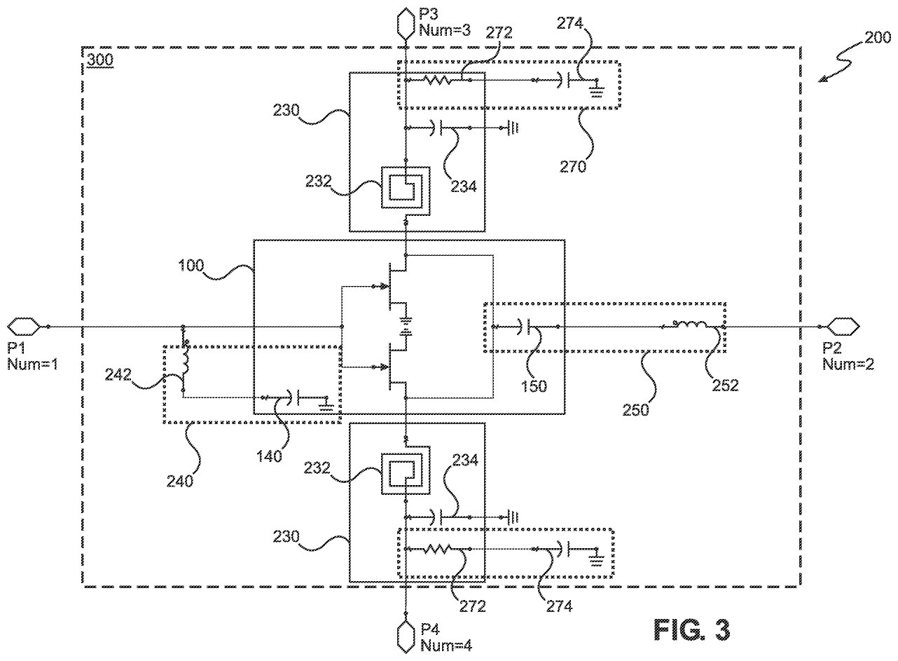

FIG. 3 illustrates a schematic of a device according to aspects of the disclosure.

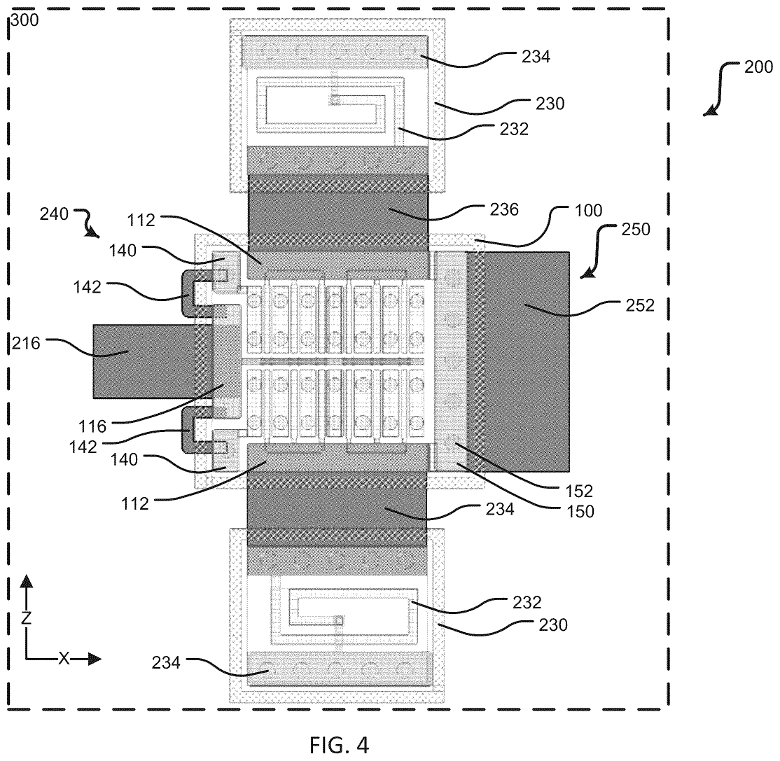

FIG. 4 illustrates a plan view of a device according to aspects of the disclosure.

In particular, FIG. 3 illustrates a schematic of a device 200 according to aspects of the disclosure. In particular, the device 200 may include the transistor die 100 and an integrated passive device (IPD) 300.

In aspects, the device 200 may implement a second harmonic circuit 240. The second harmonic circuit 240 may be implemented in part on the transistor die 100 and in part on the integrated passive device (IPD) 300. In aspects, the second harmonic circuit 240 may connect to the second harmonic control capacitor 140 arranged on the transistor die 100 and the second harmonic circuit connection 142 may be arranged on the second harmonic control capacitor 140. In particular, the second harmonic circuit 240 may be connected to the second harmonic control capacitor 140 by the second harmonic circuit connection 142. Additionally, the second harmonic circuit 240 may include an inductor 242. In particular, the inductor 242 may be connected to the second harmonic control capacitor 140 by the second harmonic circuit connection 142. In aspects, the inductor 242 may be implemented on the integrated passive device (IPD) 300.

In aspects, the device 200 may implement a shunt L circuit 230. The shunt L circuit 230 may be implemented at least in part on the device 200. In particular, the shunt L circuit 230 may be connected to the drain pads 112 by the drain pad connection 132. Additionally, the shunt L circuit 230 may include an inductor 232 and a capacitor 234. In aspects, the inductor 232 may be implemented on the integrated passive device (IPD) 300. In aspects, the capacitor 234 may be implemented on the integrated passive device (IPD) 300. In aspects, there may be two implementations of the baseband termination circuit 270 with one implementation of the drain pads 112. Further, the device 200 may be configured to receive a direct current (DC) feed. In aspects, the direct current (DC) feed may be provided to the shunt L circuit 230. In other aspects, the direct current (DC) feed may be provided other locations and/or circuits of the device 200.

Further, the capacitor 234 may be implemented with a metal insulator metal (MIM) configuration. In this regard, a first metal of the capacitor 234 may be arranged on the integrated passive device (IPD) 300, an insulator material may be arranged on the first metal, and a second metal may be arranged on the insulator material.

In aspects, the device 200 may implement a baseband termination circuit 270. The baseband termination circuit 270 may include a resistor 272 and a capacitor 274. In aspects, the resistor 272 may be implemented on the integrated passive device (IPD) 300 and may be connected to the shunt L circuit 230. In aspects, the capacitor 274 may be connected to the resistor 272. In aspects, the capacitor 274 may be implemented as a surface mount device (SMD) arranged on the integrated passive device (IPD) 300 and/or the device 200.

In aspects, the device 200 may implement a wide band application circuit 250. The wide band application circuit 250 may be implemented in part on the transistor die 100 and in part on the device 200. In aspects, the wide band application circuit 250 may include the output capacitor 150 arranged on the transistor die 100 and the capacitor connection 152 arranged on the output capacitor 150. In particular, the wide band application circuit 250 may be connected to the output capacitor 150 by the capacitor connection 152. Additionally, the wide band application circuit 250 may include an inductor 252. In particular, the inductor 252 may be connected to the output capacitor 150 by the capacitor connection 152. In aspects, the inductor 252 may be implemented on the integrated passive device (IPD) 300.

With reference to FIG. 4, the inductor 252 of the wide band application circuit 250 may be implemented as a metallic line on the integrated passive device (IPD) 300. In aspects, the inductor 252 may connect to the output capacitor 150 via the capacitor connection 152.

With further reference to FIG. 4, the second harmonic circuit connection 142 of the second harmonic circuit 240 may be implemented as a strip line extending from the second harmonic control capacitor 140 to the gate pad 116. In aspects, the second harmonic control capacitor 140 may connect to the second harmonic circuit connection 142 and an implementation of the gate pad connection 136.

With further reference to FIG. 4, a metallic line 236 may connect the shunt L circuit 230 to the drain pads 112. In particular, the metallic line 236 may connect to the drain pad connection 132 of the drain pads 112.

Additionally, the device 200 may include an input 216. In aspects, the input 216 may form the RF input for the device 200. The input 216 may connect to the gate pad connection 136 of the gate pad 116.

Further, the metallic line 236 may be the output from the transistor die 100 and the output may be transmitted along the z-axis. Additionally, the input 216 may be received by the transistor die 100 along the X axis.

In this aspect, the output of the transistor die 100 from the metallic line 236 may be transmitted along the z-axis and the input 216 received by the transistor die 100 along the X axis. Accordingly, the output from the transistor die 100 may be configured on an axis at least semi-orthogonally and/or orthogonally to an axis of the input to the input 216.

In aspects, the second harmonic control capacitor 140 and the output capacitor 150 may be implemented on the transistor die 100. In other aspects, the second harmonic control capacitor 140 may be implemented in the integrated passive device (IPD) 300; and/or the output capacitor 150 may be implemented in the integrated passive device (IPD) 300.

In aspects, implementations of the connections of the transistor die 100, such as the drain pad connection 132, the gate pad connection 136, the second harmonic circuit connection 142, the capacitor connection 162, and/or the like may be connected to the integrated passive device (IPD) 300. In aspects, the connections of the transistor die 100 may include an adhesive, soldering, sintering, eutectic bonding, ultrasonically welding, and/or the like.

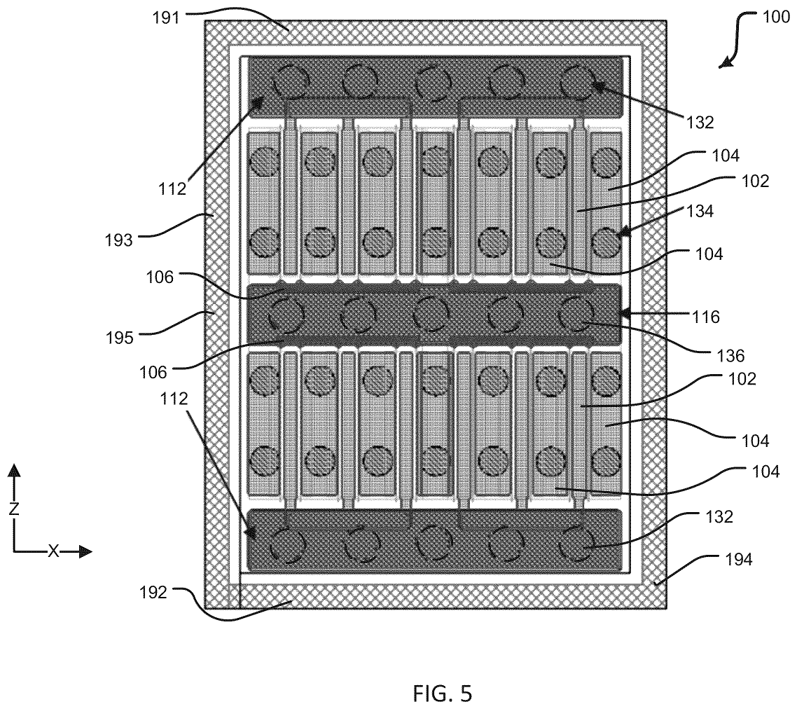

FIG. 5 illustrates a plan view of another implementation of the transistor die according to aspects of the disclosure.

In particular, FIG. 5 illustrates a plan view of another implementation of the transistor die 100 according to aspects of the disclosure. The transistor die 100 illustrated in FIG. 5 and described herewith may optionally include any other features of the transistor die 100 described in any of the other figures. Moreover, any of the other implementations in the transistor die 100 described herein may be implemented in the transistor die 100 illustrated in FIG. 5.

As illustrated in FIG. 5, the transistor die 100 is implemented without the second harmonic control capacitor 140, the output capacitor 150, and the gate pad 116 is arranged between the source fingers 104, the drain fingers 102, and the drain pads 112.

Further, the transistor die 100 may implement the gate pad 116 between implementations of the drain fingers 102 and/or the source fingers 104 on the first die side 191 and implementations of the drain fingers 102 and/or the source fingers 104 on the second die side 192. In aspects, the gate pad 116 may extend along the x axis and/or extend laterally across the transistor die 100 in the central location 195 of the transistor die 100. Further, the gate pad 116 may connect to the gate bus 106 that may include gate fingers 166 (illustrated in FIG. 12) extending along the z axis between implementations of the drain fingers 102 and the source fingers 104.

In aspects, there may be implementations of the drain fingers 102 and the source fingers 104 between the gate pad 116 and the drain pads 112 on the first die side 191; and there may be implementations of the drain fingers 102 and the source fingers 104 between the gate pad 116 and the drain pads 112 on the second die side 192.

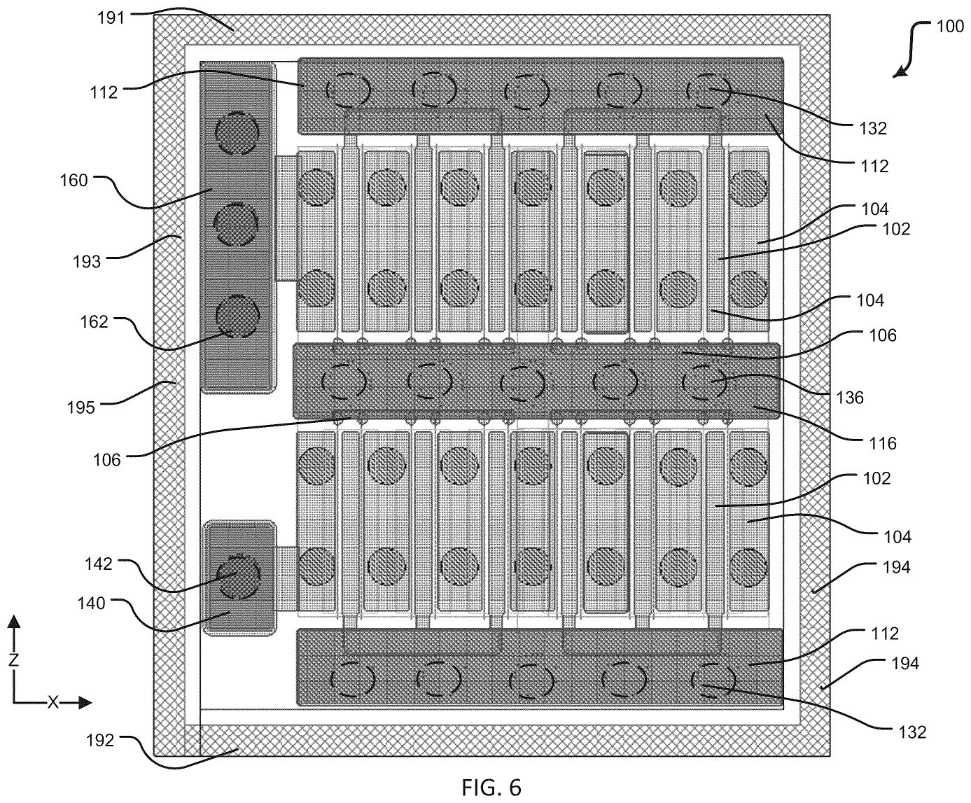

FIG. 6 illustrates a plan view of another transistor die according to aspects of the disclosure.

In particular, FIG. 6 illustrates a plan view of another transistor die 100 according to aspects of the disclosure. The transistor die 100 illustrated in FIG. 6 and described herewith may optionally include any other features of the transistor die 100 described in any of the other figures. Moreover, any of the other implementations in the transistor die 100 described herein may be implemented in the transistor die 100 illustrated in FIG. 6.

As illustrated in FIG. 6, the transistor die 100 may include a capacitor 160. The capacitor 160 may be configured as part of an F0 high pass capacitor circuit. In aspects, the capacitor 160 may be arranged adjacent the third side 193 and may extend along the z-axis from the first die side 191 to the central location 195. In aspects, the capacitor 160 may connect to the source fingers 104 implemented along the first die side 191.

In aspects, the capacitor 160 may include a capacitor connection 162. In aspects, the capacitor connection 162 may connect the capacitor 160 to the device 200. In aspects, the capacitor connection 152 may be a pillar, a Copper pillar, and/or the like.

Further, the capacitor 160 may be implemented with a metal insulator metal (MIM) configuration. In this regard, a first metal of the capacitor 160 may be arranged on the transistor die 100, an insulator material may be arranged on the first metal, and a second metal may be arranged on the insulator material.

Further, the transistor die 100 may implement the gate pad 116 between implementations of the drain fingers 102 and/or the source fingers 104 on the first die side 191 and implementations of the drain fingers 102 and/or the source fingers 104 on the second die side 192. In aspects, the gate pad 116 may extend along the x axis and/or extend laterally across the transistor die 100 in the central location 195 of the transistor die 100. Further, the gate pad 116 may connect to the gate bus 106 that may include gate fingers 166 (illustrated in FIG. 12) extending along the z axis between implementations of the drain fingers 102 and the source fingers 104.

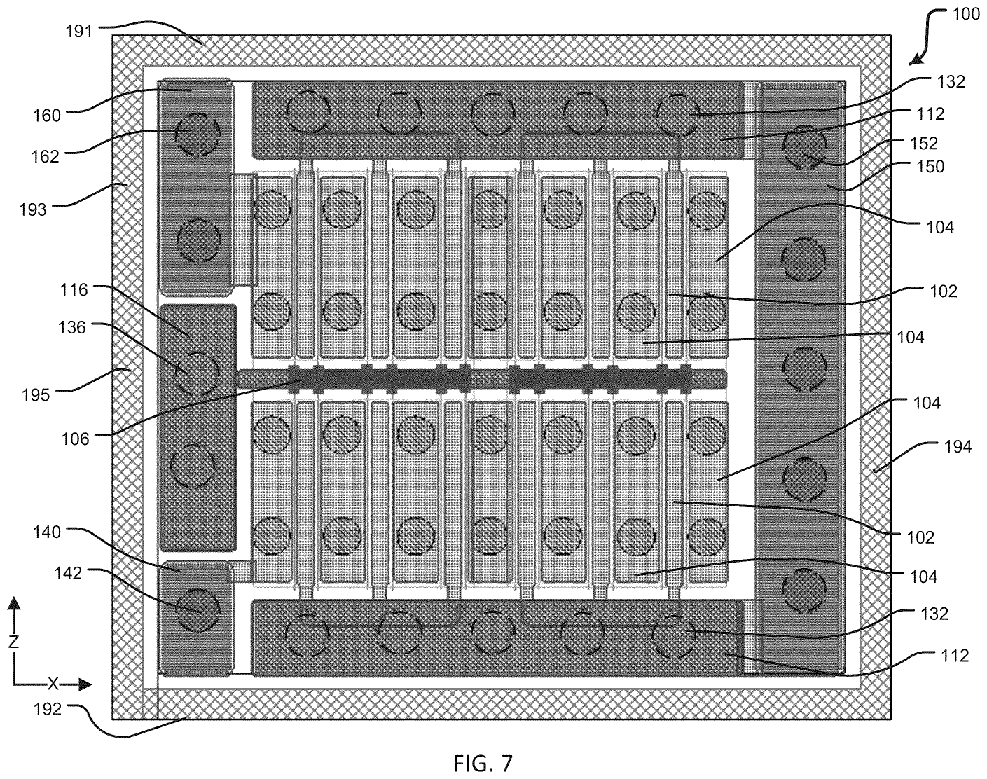

FIG. 7 illustrates a plan view of another transistor die according to aspects of the disclosure.

In particular, FIG. 7 illustrates a plan view of another transistor die 100 according to aspects of the disclosure. The transistor die 100 illustrated in FIG. 7 and described herewith may optionally include any other features of the transistor die 100 described in any of the other figures. Moreover, any of the other implementations in the transistor die 100 described herein may be implemented in the transistor die 100 illustrated in FIG. 7.

As illustrated in FIG. 7, the transistor die 100 may include the second harmonic control capacitor 140, the output capacitor 150, and the capacitor 160. Further, the implementation of the transistor die 100 and FIG. 7 may further implement the gate pad 116 generally consistent with an implementation of the gate pad 116 illustrated in FIG. 1. Additionally, the gate pad 116 may be arranged between the second harmonic control capacitor 140 and the capacitor 160.

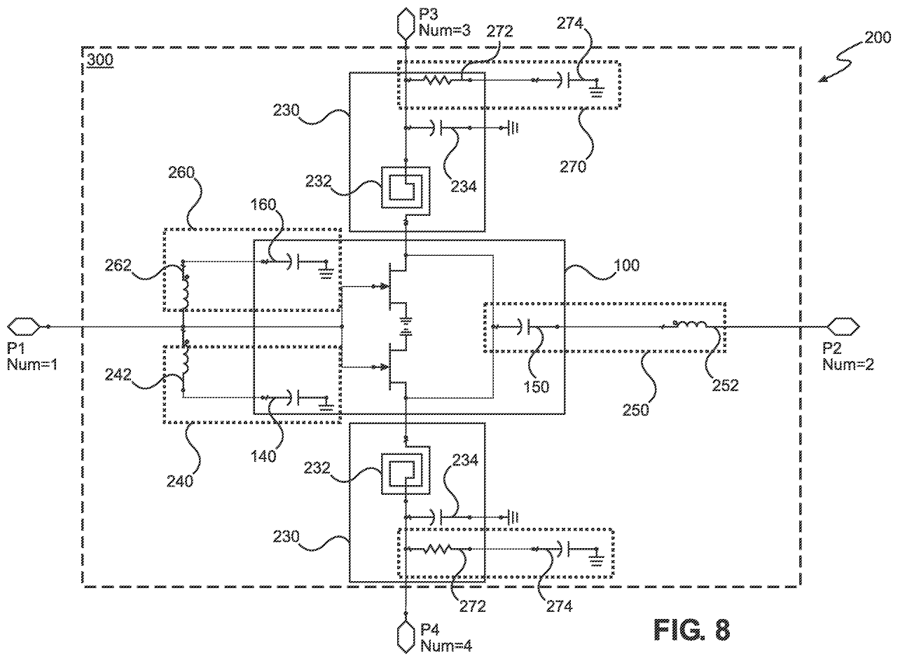

FIG. 8 illustrates a schematic of a device according to aspects of the disclosure.

In particular, FIG. 8 illustrates a schematic of a device 200 according to aspects of the disclosure. In particular, the FIG. 8 implementation of the device 200 may include the transistor die 100, the integrated passive device (IPD) 300, the second harmonic circuit 240, the shunt L circuit 230, the baseband termination circuit 270, and/or the wide band application circuit 250 as illustrated in FIG. 3 and described herewith.

In aspects, the device 200 may implement a F0 high pass capacitor circuit 260. The F0 high pass capacitor circuit 260 may be implemented in part on the transistor die 100 and in part on the integrated passive device (IPD) 300. In aspects, the F0 high pass capacitor circuit 260 may connect to the capacitor 160 arranged on the transistor die 100 and the capacitor connection 162 arranged on the capacitor 160. In particular, the F0 high pass capacitor circuit 260 may be connected to the capacitor 160 by the capacitor connection 162. Additionally, the F0 high pass capacitor circuit 260 may include an inductor 262. In particular, the inductor 262 may be connected to the capacitor 160 by the capacitor connection 162. In aspects, the inductor 262 may be implemented on the integrated passive device (IPD) 300.

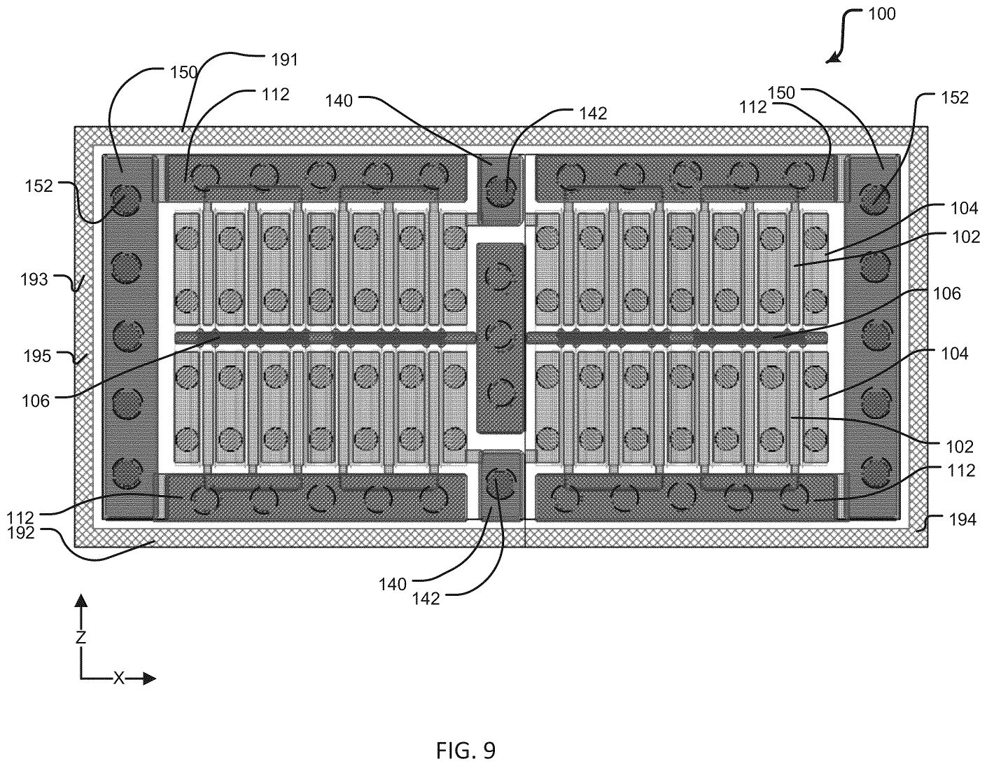

FIG. 9 illustrates a plan view of another transistor die according to aspects of the disclosure.

In particular, FIG. 9 illustrates a plan view of another transistor die 100 according to aspects of the disclosure. The transistor die 100 illustrated in FIG. 9 and described herewith may optionally include any other features of the transistor die 100 described in any of the other figures. Moreover, any of the other implementations in the transistor die 100 described herein may be implemented in the transistor die 100 illustrated in FIG. 9.

In particular, FIG. 9 illustrates the transistor die 100 implementing a configuration for higher power implementations of the device 200. More specifically, the FIG. 9 implementation of the transistor die 100 includes all the features of the FIG. 1 implementation of the transistor die 100 duplicated and mirrored with implementations of the output capacitor 150 arranged along the third side 193 and the fourth side 194. Further, the FIG. 9 implementation of the transistor die 100 may implement the second harmonic control capacitor 140 between implementations of the output capacitor 150 and/or the drain pads 112.

In aspects, the FIG. 9 implementation of the transistor die 100 may be a single integrated device for wider bandwidth performance. In other aspects, the FIG. 9 implementation of the transistor die 100 may be two separate discrete devices.

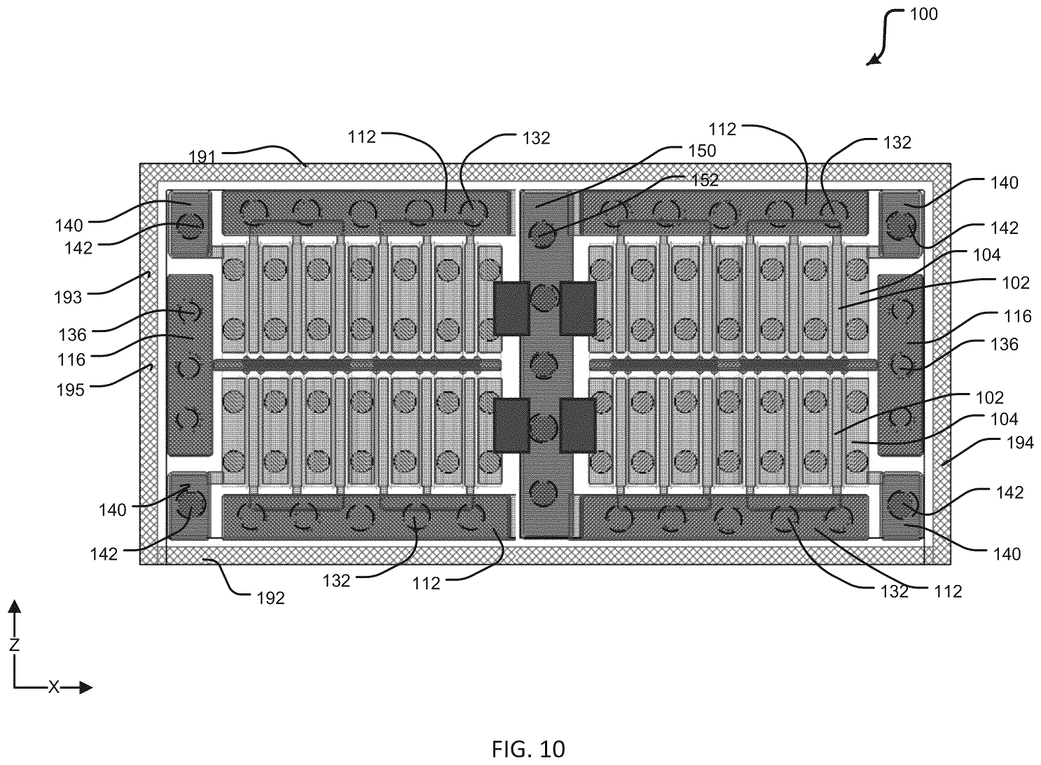

FIG. 10 illustrates a plan view of another transistor die according to aspects of the disclosure.

In particular, FIG. 10 illustrates a plan view of another transistor die 100 according to aspects of the disclosure. The transistor die 100 illustrated in FIG. 10 and described herewith may optionally include any other features of the transistor die 100 described in any of the other figures. Moreover, any of the other implementations in the transistor die 100 described herein may be implemented in the transistor die 100 illustrated in FIG. 10.

In particular, the FIG. 10 implementation of the transistor die 100 includes all the features of the FIG. 1 implementation of the transistor die 100 duplicated and mirrored with implementations of the gate pad 116 arranged along the third side 193 and the fourth side 194.

In the FIG. 10 aspects of the transistor die 100, the transistor die 100 may be implemented with two discrete dies for a Doherty implementation with ground isolation in the middle. In aspects, the FIG. 10 implementation of the transistor die 100 may be implemented in the second harmonic control capacitor 140. Alternatively, the FIG. 10 implementation of the transistor die 100 may not be implemented in the second harmonic control capacitor 140.

In aspects, the drain pads 112, the gate pad 116, the second harmonic control capacitor 140, the output capacitor 150, the capacitor 160, and/or the like may comprise a metallic material such as copper, gold, nickel, palladium, silver, tin, a gold tin alloy, and the like, and combinations thereof. In aspects, the drain pads 112, the gate pad 116, the second harmonic control capacitor 140, the output capacitor 150, the capacitor 160, and/or the like may be constructed utilizing one or more manufacturing techniques including print screening, silk screen printing processes, photoengraving processes, print onto transparent film processes, photo mask processes in combination with etching processes, photo-sensitized board processes, laser resist ablation processes, milling processes, laser etching processes, direct metal printing processes, sputtering processes, electroplating processes, photolithography processes, and/or like processes.

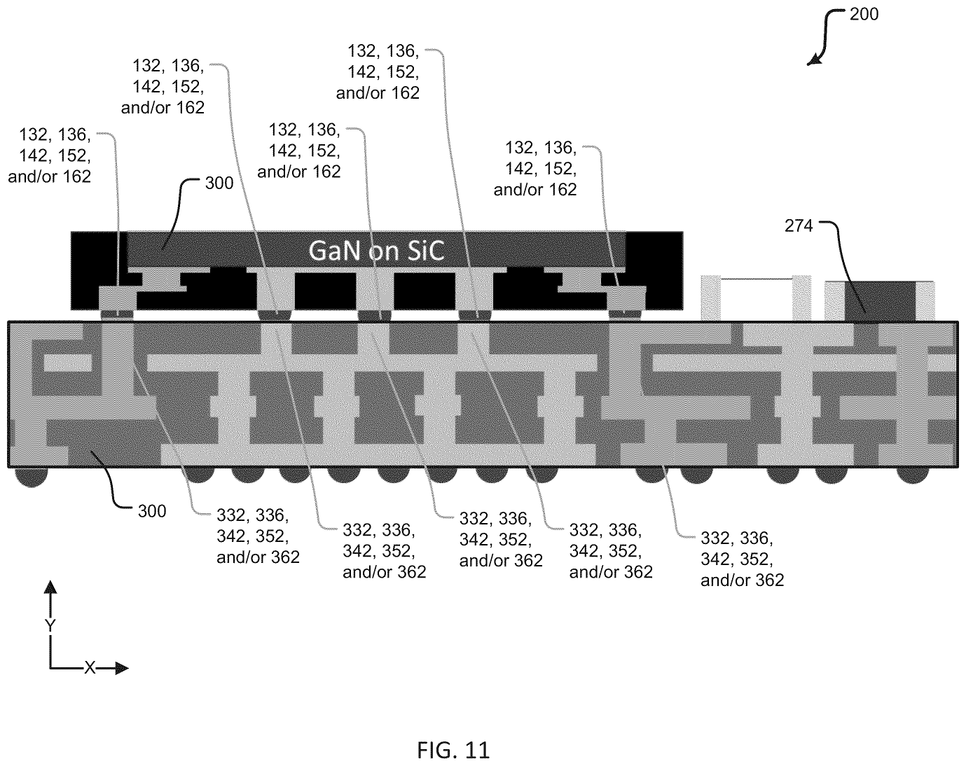

FIG. 11 is a schematic cross-sectional view of the transistor die, the device, and the integrated passive device (IPD) according to aspects of the disclosure.

In particular, FIG. 11 is a schematic cross-sectional view of the transistor die 100, the device 200, and the integrated passive device (IPD) 300 according to aspects of the disclosure. The transistor die 100, the device 200, and the integrated passive device (IPD) 300 illustrated in FIG. 11 and described herewith may optionally include any other features of the transistor die 100, the device 200, and the integrated passive device (IPD) 300 described in any of the other figures. Moreover, any of the other implementations in the transistor die 100, the device 200, and the integrated passive device (IPD) 300 described herein may be implemented in the transistor die 100, the device 200, and the integrated passive device (IPD) 300 illustrated in FIG. 11.

With reference to FIG. 11, the device 200 may include the transistor die 100 implemented as a flip chip and arranged on the integrated passive device (IPD) 300. Implementations of the drain pad connection 132, the gate pad connection 136, the second harmonic circuit connection 142, the capacitor connection 152, the capacitor connection 162, and/or the like arranged on the transistor die 100 may connect the transistor die 100 to the integrated passive device (IPD) 300.

In aspects, the integrated passive device (IPD) 300 may be implemented as a printed circuit board (PCB), a printed wiring board (PWB), a printed circuit board assembly (PCBA), a medium used to connect electronic components to one another in a controlled manner, and/or the like. In aspects, the integrated passive device (IPD) 300 may be implemented as a laminated sandwich structure of one or more conductive and insulating layers. In aspects, the integrated passive device (IPD) 300 may include one or more conductive layers, traces, planes and/or the like. In aspects, the integrated passive device (IPD) 300 may be etched from one or more sheet layers of copper laminated onto and/or between sheet layers of a non-conductive substrate. In aspects, the integrated passive device (IPD) 300 may be configured such that the transistor die 100, the capacitor 274, and/or other electrical components may be fixed to the top or bottom thereof.

In aspects, the drain pad connection 132, the gate pad connection 136, the second harmonic circuit connection 142, the capacitor connection 152, the capacitor connection 162, and/or the like may be connected to the integrated passive device (IPD) 300. In aspects, the drain pad connection 132 on the transistor die 100 may connect to a drain pad IPD connection 332 on the integrated passive device (IPD) 300. In aspects, the gate pad connection 136 on the transistor die 100 may connect to a gate pad IPD connection 336 on the integrated passive device (IPD) 300. In aspects, the second harmonic circuit connection 142 on the transistor die 100 may connect to a second harmonic circuit IPD connection 342 on the integrated passive device (IPD) 300. In aspects, the capacitor connection 152 on the transistor die 100 may connect to a capacitor connection 352 on the integrated passive device (IPD) 300. In aspects, the capacitor connection 162 on the transistor die 100 may connect to a capacitor IPD connection 362 on the integrated passive device (IPD) 300. In aspects, the connections of the transistor die 100 may include an adhesive, soldering, sintering, eutectic bonding, ultrasonically welding, and/or the like. Additionally, FIG. 11 illustrates that the capacitor 274 may be arranged on a surface of the integrated passive device (IPD) 300.

FIG. 12 is a schematic cross-sectional view of the transistor die according to aspects of the disclosure.

In particular, FIG. 12 is a schematic cross-sectional view of the transistor die 100 according to aspects of the disclosure. The transistor die 100 illustrated in FIG. 12 and described herewith may optionally include any other features of the transistor die 100 described in any of the other figures. Moreover, any of the other implementations in the transistor die 100 described herein may be implemented in the transistor die 100 illustrated in FIG. 12.

FIG. 12 illustrates exemplary implementations of the drain fingers 102, the source fingers 104, and the gate fingers 166. Additional implementations of the drain fingers 102, the source fingers 104, and the gate fingers 166 may extend along the X axis and/or additional implementations of the drain fingers 102, the source fingers 104, and the gate fingers 166 may extend laterally. As can be seen in FIG. 12, implementations of the gate fingers 166 may run along the Z-direction between a pair of adjacent ones of the drain fingers 102 and the source fingers 104. The transistor die 100 may include a plurality of unit cells 430, where each one of the plurality of unit cells 430 may include an individual transistor. One of the plurality of unit cells 430 is illustrated and includes the gate fingers 166 that may extend between adjacent ones of the drain fingers 102 and the source fingers 104. The “gate width” may refer to the distance by which the gate fingers 166 overlaps with its associated one of the drain fingers 102 and the source fingers 104 in the Z-direction. That is, “width” of the gate fingers 166 refers to the dimension of the gate fingers 166 that extends in parallel to the adjacent implementation of the drain fingers 102 and the source fingers 104 along the z-axis. Each of the plurality of unit cells 430 may share one of the drain fingers 102 and/or the source fingers 104 with one or more adjacent ones of the plurality of unit cells 430. Although a single implementation of the plurality of unit cells 430 is illustrated in FIG. 12, it will be appreciated that the transistor die 100 may include any number of the plurality of unit cells 430.

Referring to FIG. 12, the transistor die 100 may include a semiconductor structure 440 that includes a substrate 422, which may, for example, include 4 H—SiC or 6 H—SiC. A channel layer 490 may be arranged on the substrate 422, and a barrier layer 470 may be arranged on the channel layer 490 so that the channel layer 490 is between the substrate 422 and the barrier layer 470. The channel layer 490 and the barrier layer 470 may include Group III-nitride based materials, with the material of the barrier layer 470 having a higher bandgap than the material of the channel layer 490. For example, the channel layer 490 may include GaN, while the barrier layer 470 may comprise AlGaN.

Due to the difference in bandgap between the barrier layer 470 and the channel layer 490 and piezoelectric effects at the interface between the barrier layer 470 and the channel layer 490, a two-dimensional electron gas (2DEG) is induced in the channel layer 490 at a junction between the channel layer 490 and the barrier layer 470. The 2DEG acts as a highly conductive layer that allows conduction between the source and drain regions of the device that may be beneath the drain fingers 102 and the source fingers 104, respectively. The drain fingers 102 and the source fingers 104 may be on the barrier layer 470. It will be appreciated that in practice the gate fingers 166 may have dimensions that are substantially smaller than the dimensions of the drain fingers 102 and the source fingers 104, and it will also be appreciated that the drain fingers 102 and the source fingers 104 need not have the same dimensions.

The material of the gate fingers 166 may be chosen based on the composition of the barrier layer 470. However, in certain embodiments, materials capable of making a Schottky contact to a nitride based semiconductor material may be used, such as Ni, Pt, NiSix, Cu, Pd, Cr, W and/or WSiN. The drain fingers 102 and the source fingers 104 may include a metal, such as TiAlN, that can form an ohmic contact to GaN.

The transistor die 100 may include a metallization layer located on a lower surface of the substrate 422. The metallization layer may be located in a plane generally parallel to the z-axis and/or the x-axis. In one aspect, the metallization layer may be implemented as a full face metallic layer on the lower surface of the substrate 422.

As described herein, the transistor die 100 may have a semi-orthogonal or orthogonal gate layout. In aspects, the transistor die 100 may have a semi-orthogonal or orthogonal gate layout and the transistor die 100 may be implemented as field effect transistor. In aspects, the transistor die 100 may implement a semi-orthogonal or orthogonal gate layout and the transistor die 100 may be implemented a flip-chip field effect transistor. As further described herein, the device 200, the transistor die 100, and/or the integrated passive device (IPD) 300 may be configured and implemented in RF power products for base stations, such as 4G base stations, 5G base station, and/or the like. As described herein, the device 200, the transistor die 100, and/or the integrated passive device (IPD) 300 may be configured and/or implemented to provide greater broadband and higher efficiency.

In aspects, the device 200 may implement the transistor die 100 that has a semi-orthogonal gate layout and/or an orthogonal gate layout to a RF path. Further, in aspects of the device 200, the transistor die 100 may implement drain pads (also can be the gate pad) on both sides of the transistor die 100. Additionally, a configuration of the device 200 and the transistor die 100 may be configured to be flexible for the output pre-matching.

In aspects, the device 200 may implement the transistor die 100 with flip-chip technology. Accordingly, implementations of the device 200 as described herein together with the flip-chip technology implementation of the transistor die 100, may result in a capacitance of the pads being lower, which is beneficial for broadband designs and/or implementations. Further, the device 200 may be configured such that a coupling of the RF path and shunt L circuits is lower, which helps to implement higher efficiency.

In aspects, the device 200 may be implemented such that DC is feed through the shunt L circuit 230, the output capacitor 150 may be arranged on the transistor die 100, together with a microstrip line to implement a series LC resonator, which can compensate for an impedance change over frequency from a shunt L matching network. This configuration the transistor die 100 and/or the device 200 may further improve the bandwidth.

In aspects, the transistor die 100 may implement a split finger structure. Moreover, the device 200 may implement an output match in X and Y directions, which may be flexible for a design and/or implementation. Further, the device 200 may be configured such that DC may be fed through the shunt L circuits, which can be integrated in the series capacitor on the transistor die 100, to obtain wider bandwidth. Additionally, the device 200 may be configured such that there is lower coupling between a tuning wire and a drain wire, when bonding wires are used, which can further improve the efficiency.

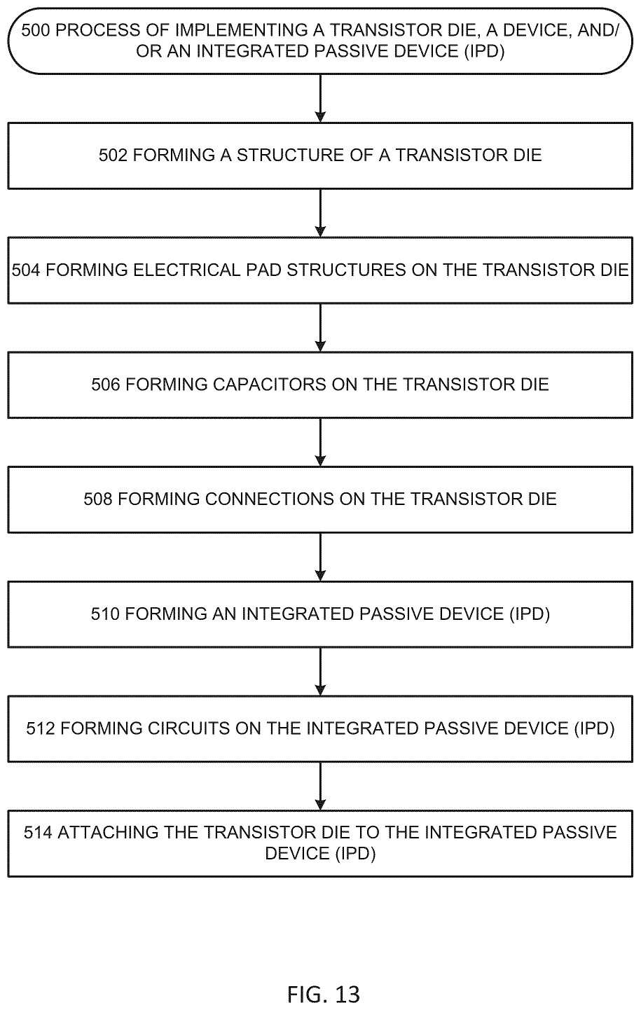

FIG. 13 illustrates an exemplary process of implementing a transistor die, a device, and/or an integrated passive device (IPD).

In particular, FIG. 13 illustrates an exemplary process of implementing a transistor die, a device, and/or an integrated passive device (IPD) 500. The process of implementing a transistor die, a device, and/or an integrated passive device (IPD) 500 may relate to a process of implementing the transistor die 100, the device 200, and/or the integrated passive device (IPD) 300 as described herein.

The process of implementing a transistor die, a device, and/or an integrated passive device (IPD) 500 illustrated in FIG. 13 and described herewith may optionally include any other features of the transistor die 100, the device 200, and the integrated passive device (IPD) 300 described in any of the other figures. Moreover, any of the other implementations in the transistor die 100, the device 200, and the integrated passive device (IPD) 300 described herein may be implemented in the process of implementing a transistor die, a device, and/or an integrated passive device (IPD) 500 illustrated in FIG. 13.

In particular, it should be noted that the process of implementing a transistor die, a device, and/or an integrated passive device (IPD) 500 is merely exemplary and may be modified consistent with the various aspects disclosed herein. Moreover, the process of implementing a transistor die, a device, and/or an integrated passive device (IPD) 500 of the disclosure may include a process of manufacturing the device 200, the transistor die 100, and/or the integrated passive device (IPD) 300. It should be noted that the process of implementing a transistor die, a device, and/or an integrated passive device (IPD) 500 may be performed in a different order consistent with the aspects described above. Moreover, the process of implementing a transistor die, a device, and/or an integrated passive device (IPD) 500 may be modified to have more or fewer process steps consistent with the various aspects disclosed herein.

The process of implementing a transistor die, a device, and/or an integrated passive device (IPD) 500 of the disclosure may include forming a structure of a transistor die 502. In this regard, the forming a structure of a transistor die 502 may include any one or more materials, structures, arrangements, processes, and/or the like as described herein. Moreover, one or more proceeding or subsequent processes may also be implemented with respect to the forming a structure of a transistor die 502 consistent with the disclosure.

In particular aspects, the forming a structure of a transistor die 502 may include forming a structure of the transistor die 100 including forming and/or structuring the 422, the 490, the 470, the 430, the 440, the drain fingers 102, the source fingers 104, the gate fingers 166, and/or the like as described herein.

The process of implementing a transistor die, a device, and/or an integrated passive device (IPD) 500 of the disclosure may include forming electrical pad structures on the transistor die 504. In this regard, the forming electrical pad structures on the transistor die 504 may include any one or more materials, structures, arrangements, processes, and/or the like as described herein. Moreover, one or more proceeding or subsequent processes may also be implemented with respect to the forming electrical pad structures on the transistor die 504 consistent with the disclosure.

In particular aspects, the forming electrical pad structures on the transistor die 504 may include forming and/or structuring the gate bus 106, the drain pads 112, the gate pad 116, and/or the like on the transistor die 100 as described herein. In aspects, the forming electrical pad structures on the transistor die 504 may include forming and/or structuring the gate bus 106, the drain pads 112, the gate pad 116, and/or the like on the transistor die 100 utilizing one or more manufacturing techniques including print screening, silk screen printing processes, photoengraving processes, print onto transparent film processes, photo mask processes in combination with etching processes, photo-sensitized board processes, laser resist ablation processes, milling processes, laser etching processes, direct metal printing processes, sputtering processes, electroplating processes, photolithography processes, and/or like processes.

The process of implementing a transistor die, a device, and/or an integrated passive device (IPD) 500 of the disclosure may include forming capacitors on the transistor die 506. In this regard, the forming capacitors on the transistor die 506 may include any one or more materials, structures, arrangements, processes, and/or the like as described herein. Moreover, one or more proceeding or subsequent processes may also be implemented with respect to the forming capacitors on the transistor die 506 consistent with the disclosure.

In particular aspects, the forming capacitors on the transistor die 506 may include forming and/or structuring the second harmonic control capacitor 140, the output capacitor 150, the capacitor 160, and/or the like on the transistor die 100 as described herein. In particular aspects, the forming capacitors on the transistor die 506 may include forming and/or structuring the second harmonic control capacitor 140, the output capacitor 150, the capacitor 160, and/or the like on the transistor die 100 utilizing one or more manufacturing techniques including print screening, silk screen printing processes, photoengraving processes, print onto transparent film processes, photo mask processes in combination with etching processes, photo-sensitized board processes, laser resist ablation processes, milling processes, laser etching processes, direct metal printing processes, sputtering processes, electroplating processes, photolithography processes, and/or like processes. The process of implementing a transistor die, a device, and/or an integrated passive device (IPD) 500 of the disclosure may include forming connections on the transistor die 508. In this regard, the forming connections on the transistor die 508 may include any one or more materials, structures, arrangements, processes, and/or the like as described herein. Moreover, one or more proceeding or subsequent processes may also be implemented with respect to the forming connections on the transistor die 508 consistent with the disclosure.

In particular aspects, the forming connections on the transistor die 508 may include forming the drain pad connection 132, the gate pad connection 136, the second harmonic circuit connection 142, the capacitor connection 162, and/or the like as described herein.

The process of implementing a transistor die, a device, and/or an integrated passive device (IPD) 500 of the disclosure may include forming an integrated passive device (IPD) 510. In this regard, the forming an integrated passive device (IPD) 510 may include any one or more materials, structures, arrangements, processes, and/or the like as described herein. Moreover, one or more proceeding or subsequent processes may also be implemented with respect to the forming an integrated passive device (IPD) 510 consistent with the disclosure.

In particular aspects, the forming an integrated passive device (IPD) 510 may include forming the integrated passive device (IPD) 300 as described herein. In particular aspects, the forming an integrated passive device (IPD) 510 may include forming the integrated passive device (IPD) 300 as a printed circuit board (PCB), a printed wiring board (PWB), a printed circuit board assembly (PCBA), a medium used to connect electronic components to one another in a controlled manner, and/or the like. In aspects, the integrated passive device (IPD) 300 may be formed as a laminated sandwich structure of one or more conductive and insulating layers. In aspects, the integrated passive device (IPD) 300 may include one or more conductive layers, traces, planes and/or the like. In aspects, the integrated passive device (IPD) 300 may be etched from one or more sheet layers of copper laminated onto and/or between sheet layers of a non-conductive substrate. In aspects, the integrated passive device (IPD) 300 may be configured such that the transistor die 100, the capacitor 274, and/or other electrical components may be fixed to the top or bottom thereof.

The process of implementing a transistor die, a device, and/or an integrated passive device (IPD) 500 of the disclosure may include forming circuits on the integrated passive device (IPD) 512. In this regard, the forming circuits on the integrated passive device (IPD) 512 may include any one or more materials, structures, arrangements, processes, and/or the like as described herein. Moreover, one or more proceeding or subsequent processes may also be implemented with respect to the forming circuits on the integrated passive device (IPD) 512 consistent with the disclosure.

In particular aspects, the forming circuits on the integrated passive device (IPD) 512 may include forming and/or structuring the shunt L circuit 230, the second harmonic circuit 240, the F0 high pass capacitor circuit 260, the wide band application circuit 250, and/or the like on the integrated passive device (IPD) 300.

The process of implementing a transistor die, a device, and/or an integrated passive device (IPD) 500 of the disclosure may include attaching the transistor die to the integrated passive device (IPD) 514. In this regard, the attaching the transistor die to the integrated passive device (IPD) 514 may include any one or more materials, structures, arrangements, processes, and/or the like as described herein. Moreover, one or more proceeding or subsequent processes may also be implemented with respect to the attaching the transistor die to the integrated passive device (IPD) 514 consistent with the disclosure.

In particular aspects, the attaching the transistor die to the integrated passive device (IPD) 514 may include attaching the transistor die 100 to the integrated passive device (IPD) 300 as described herein. In particular aspects, the attaching the transistor die to the integrated passive device (IPD) 514 may include flipping and attaching the transistor die 100 to the integrated passive device (IPD) 300. Further, the attaching the transistor die to the integrated passive device (IPD) 514 may include utilizing an adhesive, soldering, sintering, eutectic bonding, ultrasonically welding, and/or the like.

In aspects, the drain pad connection 132, the gate pad connection 136, the second harmonic circuit connection 142, the capacitor connection 152, the capacitor connection 162, and/or the like may be connected to the integrated passive device (IPD) 300. In aspects, the drain pad connection 132 on the transistor die 100 may connect to a drain pad IPD connection 332 on the integrated passive device (IPD) 300. In aspects, the gate pad connection 136 on the transistor die 100 may connect to a gate pad IPD connection 336 on the integrated passive device (IPD) 300. In aspects, the second harmonic circuit connection 142 on the transistor die 100 may connect to a second harmonic circuit IPD connection 342 on the integrated passive device (IPD) 300. In aspects, the capacitor connection 152 on the transistor die 100 may connect to a capacitor connection 352 on the integrated passive device (IPD) 300. In aspects, the capacitor connection 162 on the transistor die 100 may connect to a capacitor IPD connection 362 on the integrated passive device (IPD) 300.

In particular aspects, the device 200 of the disclosure may be utilized in wireless base stations that connect to a wireless device. In further aspects, the device 200 of the disclosure may be utilized in amplifiers implemented by wireless base stations that connect to a wireless device. In further aspects, the device 200 of the disclosure may be utilized in wireless devices. In further aspects, the device 200 of the disclosure may be utilized in amplifiers implemented in wireless devices.

In particular aspects, the device 200 of the disclosure may be utilized in wireless base stations that connect to a wireless device. In further aspects, the device 200 of the disclosure may be utilized in amplifiers implemented by wireless base stations that connect to a wireless device. In further aspects, the device 200 of the disclosure may be utilized in wireless devices. In further aspects, the device 200 of the disclosure may be utilized in amplifiers implemented in wireless devices.

The following are a number of nonlimiting EXAMPLES of aspects of the disclosure.

One EXAMPLE includes: A transistor may include at least one drain pad arranged at a first die side of the transistor die and/or at a second die side of the transistor die, the first die side and the second die side being opposed sides of the transistor die. Transistor may also include drain fingers configured to extend from the at least one drain pad longitudinally toward a central location of the transistor die. Transistor may furthermore include source fingers configured to extend from the at least one drain pad longitudinally toward the central location of the transistor die. Transistor may in addition include a gate pad and a gate and the gate is configured to extend along implementations of the drain fingers and/or the source fingers. Transistor may moreover include where the gate pad is arranged on an axis at least semi-orthogonally to an axis of the at least one drain pad.

The above-noted EXAMPLE may further include any one or a combination of more than one of the following EXAMPLES:

The transistor includes where an output from the transistor die from the at least one drain pad is arranged on an axis at least semi-orthogonally to an axis of an input to the gate pad. The transistor also includes where the at least one drain pad may include a dimension extending laterally across the transistor die greater than a dimension longitudinally along the transistor die; and where the gate pad may include a dimension longitudinally along the transistor die greater than a dimension extending laterally across the transistor die. The transistor further includes where a longer dimension of the gate pad extends longitudinally along the transistor die; and where a longer dimension of the at least one drain pad extends laterally across the transistor die. The transistor in addition includes where the drain fingers may include multiple parallel implementations extending laterally across the transistor die; and where the source fingers may include multiple parallel implementations extending laterally across the transistor die. The transistor moreover includes where the drain fingers may include a dimension longitudinally along the transistor die greater than a dimension extending laterally across the transistor die; and where the source fingers have a dimension longitudinally along the transistor die greater than a dimension extending laterally across the transistor die. The transistor also includes where the at least one drain pad are configured to provide an output from a third die side, where the third die side is connected to the first die side and the second die side. The transistor further includes where the at least one drain pad are configured to provide an output from a fourth die side, where the fourth die side is connected to the first die side and the second die side. The transistor in addition includes where the gate pad is configured to extend longitudinally along the transistor die; and where the at least one drain pad are configured to extend laterally across the transistor die. The transistor moreover includes where the at least one drain pad may include drain pads; and where the drain fingers and the source fingers are arranged between the drain pads. The transistor also includes where an implementation of the drain pads is arranged closer to the first die side than the source fingers and/or the drain fingers; and where an implementation of the drain pads is arranged closer to the second die side than the source fingers and/or the drain fingers. The transistor further includes where the drain pads are configured to provide an output from a third die side, where the third die side is connected to the first die side and the second die side; and where the drain pads are configured to provide an output from a fourth die side, where the fourth die side is connected to the first die side and the second die side. The transistor in addition includes where the source fingers and/or the drain fingers are arranged closer to a central location of the transistor die than the implementations of the at least one drain pad. The transistor moreover includes where the gate pad is arranged on an axis at least orthogonally to an axis of the implementations of the at least one drain pad. The transistor also includes where the transistor die is configured as a flip chip. The transistor further includes may include: a drain pad connection arranged on the at least one drain pad, where the drain pad connection is a pillar; and a source connection arranged on the source fingers, where the source connection is a pillar. The transistor in addition includes may include a second harmonic control capacitor arranged on the transistor die, where the second harmonic control capacitor may include a second harmonic circuit connection; and where the second harmonic circuit connection connects the second harmonic control capacitor and/or the source fingers to a device. The transistor moreover includes where the second harmonic circuit connection may include a pillar. The transistor also includes where the second harmonic control capacitor is implemented with a metal insulator metal (MIM) configuration arranged on the transistor die. The transistor further includes may include an output capacitor arranged on the transistor die and configured as an output series capacitor. The transistor in addition includes where the output capacitor connects to an implementation of the at least one drain pad. The transistor moreover includes where the output capacitor may include a capacitor connection to a device. The transistor also includes where the capacitor connection may include a pillar. The transistor further includes where the output capacitor is implemented with a metal insulator metal (MIM) configuration arranged on the transistor die. The device in addition includes and may include an integrated passive device (IPD). The device moreover includes where the device implements a second harmonic circuit implemented in part on the transistor die and in part on the integrated passive device (IPD). The device also includes where the second harmonic circuit connects to a second harmonic control capacitor arranged on the transistor die. The device further includes where the second harmonic circuit may include an inductor connected to the second harmonic control capacitor by a second harmonic circuit connection; and where the inductor is implemented on the integrated passive device (IPD). The device in addition includes may include a shunt L circuit implemented at least in part on the device and connected to the at least one drain pad by a drain pad connection. The device moreover includes where the shunt L circuit may include an inductor and a capacitor. The device also includes where the shunt L circuit is configured to receive a direct current (DC) feed. The device further includes may include a baseband termination circuit that may include a resistor and a capacitor implemented on the integrated passive device (IPD). The device in addition includes may include a wide band application circuit that may include an output capacitor arranged on the transistor die. The device moreover includes may include: an input configured to form an RF input for the device and the input being connected to the gate pad; and an output configured to form an RF output for the device and the output being connected to the at least one drain pad; and where the output is configured on an axis at least semi-orthogonally to an axis of the input. The device also includes may include a capacitor configured as part of F0 high pass capacitor circuit connected to the source fingers. The device further includes where the capacitor is implemented with a metal insulator metal (MIM) configuration arranged on the transistor die. The device in addition includes where the transistor die may include two separate transistor devices combined. The device moreover includes where the transistor die may include two separate discrete transistor devices. The device also includes may include a second transistor, where the transistor and the second transistor may include two separate discrete devices configured in a Doherty implementation.

One EXAMPLE includes: A transistor may include drain pads arranged at a first die side of the transistor die and at a second die side of the transistor die, the first die side and the second die side being opposed sides of the transistor die. Transistor may also include drain fingers arranged at the first die side of the transistor die and the second die side of the transistor die. Transistor may furthermore include source fingers arranged at the first die side of the transistor die and a second die side of the transistor die. Transistor may in addition include a gate pad and a gate and the gate configured to extend along implementations of the drain fingers and/or the source fingers on the first die side and implementations of the drain fingers and/or the source fingers on the second die side.

The above-noted EXAMPLE may further include any one or a combination of more than one of the following EXAMPLES:

The transistor includes where the drain pads may include a dimension extending laterally across the transistor die greater than a dimension longitudinally along the transistor die; and where the gate pad may include a dimension longitudinally along the transistor die greater than a dimension extending laterally across the transistor die. The transistor also includes where a longer dimension of the gate pad extends longitudinally along the transistor die; and where a longer dimension of the drain pads extends laterally across the transistor die. The transistor further includes where the drain fingers are configured to extend from the drain pads longitudinally toward a central location of the transistor die; where the source fingers are configured to extend from the drain pads longitudinally toward the central location of the transistor die; and where implementations of the source fingers are adjacent each implementation of the drain fingers. The transistor in addition includes where the drain fingers may include multiple parallel implementations extending laterally across the transistor die; and where the source fingers may include multiple parallel implementations extending laterally across the transistor die. The transistor moreover includes where the drain fingers may include a dimension longitudinally along the transistor die greater than a dimension extending laterally across the transistor die; and where the source fingers have a dimension longitudinally along the transistor die greater than a dimension extending laterally across the transistor die. The transistor also includes where the drain fingers and the source fingers are arranged between the drain pads. The transistor further includes where an implementation of the drain pads is arranged closer to the first die side than the source fingers and/or the drain fingers; and where an implementation of the drain pads is arranged closer to the second die side than the source fingers and/or the drain fingers. The transistor in addition includes where the source fingers and/or the drain fingers are arranged closer to a central location of the transistor die than the implementations of the drain pads. The transistor moreover includes where the drain pads are configured to provide an output from a third die side, where the third die side is connected to the first die side and the second die side. The transistor also includes where the drain pads are configured to provide an output from a fourth die side, where the fourth die side is connected to the first die side and the second die side. The transistor further includes where the drain pads are configured to provide an output from a third die side, where the third die side is connected to the first die side and the second die side; and where the drain pads are configured to provide an output from a fourth die side, where the fourth die side is connected to the first die side and the second die side. The transistor in addition includes where the gate pad is configured to extend longitudinally along the transistor die; and where the drain pads are configured to extend laterally across the transistor die. The transistor moreover includes where the drain pads are configured to extend laterally across the transistor die; and where the gate pad is configured to extend laterally across the transistor die between the drain pads. The transistor also includes where the gate pad is arranged on an axis at least semi-orthogonally to an axis of the implementations of the drain pads. The transistor further includes where the gate pad is arranged on an axis at least orthogonally to an axis of the implementations of the drain pads. The transistor in addition includes where an output from the transistor die from the drain pads is arranged on an axis at least semi-orthogonally to an axis of an input to the gate pad. The transistor moreover includes where the transistor die is configured as a flip chip. The transistor also includes may include: a drain pad connection arranged on the drain pads, where the drain pad connection is a pillar; and a source connection arranged on the source fingers, where the source connection is a pillar. The transistor further includes may include a second harmonic control capacitor arranged on the transistor die, where the second harmonic control capacitor may include a second harmonic circuit connection; and where the second harmonic circuit connection connects the second harmonic control capacitor and/or the source fingers to a device. The transistor in addition includes where the second harmonic circuit connection may include a pillar. The transistor moreover includes where the second harmonic control capacitor is implemented with a metal insulator metal (MIM) configuration arranged on the transistor die. The transistor also includes may include an output capacitor arranged on the transistor die and configured as an output series capacitor. The transistor further includes where the output capacitor connects to an implementation of the drain pads. The transistor in addition includes where the output capacitor may include a capacitor connection to a device. The transistor moreover includes where the capacitor connection may include a pillar. The transistor also includes where the output capacitor is implemented with a metal insulator metal (MIM) configuration arranged on the transistor die. The device further includes and may include an integrated passive device (IPD). The device in addition includes where the device implements a second harmonic circuit implemented in part on the transistor die and in part on the integrated passive device (IPD). The device moreover includes where the second harmonic circuit connects to a second harmonic control capacitor arranged on the transistor die. The device also includes where the second harmonic circuit may include an inductor connected to the second harmonic control capacitor by a second harmonic circuit connection; and where the inductor is implemented on the integrated passive device (IPD). The device further includes may include a shunt L circuit implemented at least in part on the device and connected to the drain pads by a drain pad connection. The device in addition includes where the shunt L circuit may include an inductor and a capacitor. The device moreover includes where the shunt L circuit is configured to receive a direct current (DC) feed. The device also includes may include a baseband termination circuit that may include a resistor and a capacitor implemented on the integrated passive device (IPD). The device further includes may include a wide band application circuit that may include an output capacitor arranged on the transistor die. The device in addition includes may include: an input configured to form an RF input for the device and the input being connected to the gate pad; and an output configured to form an RF output for the device and the output being connected to the drain pads; and where the output is configured on an axis at least semi-orthogonally to an axis of the input. The device moreover includes may include a capacitor configured as part of F0 high pass capacitor circuit connected to the source fingers. The device also includes where the capacitor is implemented with a metal insulator metal (MIM) configuration arranged on the transistor die. The device further includes where the transistor die may include two separate transistor devices combined. The device in addition includes where the transistor die may include two separate discrete transistor devices. The device moreover includes may include a second transistor, where the transistor and the second transistor may include two separate discrete devices configured in a Doherty implementation.

One EXAMPLE includes: A process may include arranging at least one drain pad at a first die side of the transistor die and/or at a second die side of the transistor die, the first die side and the second die side being opposed sides of the transistor die. Process may also include configuring drain fingers to extend from the at least one drain pad longitudinally toward a central location of the transistor die. Process may furthermore include configuring source fingers to extend from the at least one drain pad longitudinally toward the central location of the transistor die. Process may in addition include arranging a gate pad on an axis at least semi-orthogonally to an axis of the at least one drain pad. Process may moreover include configuring a gate to extend along implementations of the drain fingers and/or the source fingers.

The above-noted EXAMPLE may further include any one or a combination of more than one of the following EXAMPLES:

The process includes where an output from the transistor die from the at least one drain pad is arranged on an axis at least semi-orthogonally to an axis of an input to the gate pad. The process also includes where the at least one drain pad may include a dimension extending laterally across the transistor die greater than a dimension longitudinally along the transistor die; and where the gate pad may include a dimension longitudinally along the transistor die greater than a dimension extending laterally across the transistor die. The process further includes where a longer dimension of the gate pad extends longitudinally along the transistor die; and where a longer dimension of the at least one drain pad extends laterally across the transistor die. The process in addition includes where the drain fingers may include multiple parallel implementations extending laterally across the transistor die; and where the source fingers may include multiple parallel implementations extending laterally across the transistor die. The process moreover includes where the drain fingers may include a dimension longitudinally along the transistor die greater than a dimension extending laterally across the transistor die; and where the source fingers have a dimension longitudinally along the transistor die greater than a dimension extending laterally across the transistor die. The process also includes where the at least one drain pad are configured to provide an output from a third die side, where the third die side is connected to the first die side and the second die side. The process further includes where the at least one drain pad are configured to provide an output from a fourth die side, where the fourth die side is connected to the first die side and the second die side. The process in addition includes where the gate pad is configured to extend longitudinally along the transistor die; and where the at least one drain pad are configured to extend laterally across the transistor die. The process moreover includes where the at least one drain pad may include drain pads; and where the drain fingers and the source fingers are arranged between the drain pads. The process also includes where an implementation of the drain pads is arranged closer to the first die side than the source fingers and/or the drain fingers; and where an implementation of the drain pads is arranged closer to the second die side than the source fingers and/or the drain fingers. The process further includes where the drain pads are configured to provide an output from a third die side, where the third die side is connected to the first die side and the second die side; and where the drain pads are configured to provide an output from a fourth die side, where the fourth die side is connected to the first die side and the second die side. The process in addition includes where the source fingers and/or the drain fingers are arranged closer to a central location of the transistor die than the implementations of the at least one drain pad. The process moreover includes where the gate pad is arranged on an axis at least orthogonally to an axis of the implementations of the at least one drain pad. The process also includes where the transistor die is configured as a flip chip. The process further includes may include: arranging a drain pad connection on the at least one drain pad, where the drain pad connection is a pillar; and arranging a source connection on the source fingers, where the source connection is a pillar. The process in addition includes may include arranging a second harmonic control capacitor on the transistor die, where the second harmonic control capacitor may include a second harmonic circuit connection; and where the second harmonic circuit connection connects the second harmonic control capacitor and/or the source fingers to a device. The process moreover includes where the second harmonic circuit connection may include a pillar. The process also includes where the second harmonic control capacitor is implemented with a metal insulator metal (MIM) configuration arranged on the transistor die. The process further includes may include arranging an output capacitor on the transistor die and configured as an output series capacitor. The process in addition includes where the output capacitor connects to an implementation of the at least one drain pad. The process moreover includes where the output capacitor may include a capacitor connection to a device. The process also includes where the capacitor connection may include a pillar. The process further includes where the output capacitor is implemented with a metal insulator metal (MIM) configuration arranged on the transistor die. The process in addition includes and may include implementing an integrated passive device (IPD). The process moreover includes where the device implements a second harmonic circuit implemented in part on the transistor die and in part on the integrated passive device (IPD). The process also includes where the second harmonic circuit connects to a second harmonic control capacitor arranged on the transistor die. The process further includes where the second harmonic circuit may include an inductor connected to the second harmonic control capacitor by a second harmonic circuit connection; and where the inductor is implemented on the integrated passive device (IPD). The process in addition includes may include implementing a shunt L circuit at least in part on the device and connected to the at least one drain pad by a drain pad connection. The process moreover includes where the shunt L circuit may include an inductor and a capacitor. The process also includes where the shunt L circuit is configured to receive a direct current (DC) feed. The process further includes may include implementing a baseband termination circuit that may include a resistor and a capacitor implemented on the integrated passive device (IPD). The process in addition includes may include implementing a wide band application circuit that may include an output capacitor arranged on the transistor die. The process moreover includes may include: configuring an input to form an RF input for the device and the input being connected to the gate pad; and configuring an output to form an RF output for the device and the output being connected to the at least one drain pad; and where the output is configured on an axis at least semi-orthogonally to an axis of the input. The process also includes may include configuring a capacitor as part of F0 high pass capacitor circuit connected to the source fingers. The process further includes where the capacitor is implemented with a metal insulator metal (MIM) configuration arranged on the transistor die. The process in addition includes where the transistor die may include two separate transistor devices combined. The process moreover includes where the transistor die may include two separate discrete transistor devices. The process also includes may include implementing a second transistor, where the transistor and the second transistor may include two separate discrete devices configured in a Doherty implementation.

One EXAMPLE includes: A process may include arranging drain pads at a first die side of the transistor die and at a second die side of the transistor die, the first die side and the second die side being opposed sides of the transistor die. Process may also include arranging drain fingers at the first die side of the transistor die and the second die side of the transistor die. Process may furthermore include arranging source fingers at the first die side of the transistor die and a second die side of the transistor die. Process may in addition include providing a gate pad. Process may moreover include configuring a gate to extend along implementations of the drain fingers and/or the source fingers on the first die side and implementations of the drain fingers and/or the source fingers on the second die side.

The above-noted EXAMPLE may further include any one or a combination of more than one of the following EXAMPLES:

The process includes where the drain pads may include a dimension extending laterally across the transistor die greater than a dimension longitudinally along the transistor die; and where the gate pad may include a dimension longitudinally along the transistor die greater than a dimension extending laterally across the transistor die. The process also includes where a longer dimension of the gate pad extends longitudinally along the transistor die; and where a longer dimension of the drain pads extends laterally across the transistor die. The process further includes where the drain fingers are configured to extend from the drain pads longitudinally toward a central location of the transistor die; where the source fingers are configured to extend from the drain pads longitudinally toward the central location of the transistor die; and where implementations of the source fingers are adjacent each implementation of the drain fingers. The process in addition includes where the drain fingers may include multiple parallel implementations extending laterally across the transistor die; and where the source fingers may include multiple parallel implementations extending laterally across the transistor die. The process moreover includes where the drain fingers may include a dimension longitudinally along the transistor die greater than a dimension extending laterally across the transistor die; and where the source fingers have a dimension longitudinally along the transistor die greater than a dimension extending laterally across the transistor die. The process also includes where the drain fingers and the source fingers are arranged between the drain pads. The process further includes where an implementation of the drain pads is arranged closer to the first die side than the source fingers and/or the drain fingers; and where an implementation of the drain pads is arranged closer to the second die side than the source fingers and/or the drain fingers. The process in addition includes where the source fingers and/or the drain fingers are arranged closer to a central location of the transistor die than the implementations of the drain pads. The process moreover includes where the drain pads are configured to provide an output from a third die side, where the third die side is connected to the first die side and the second die side. The process also includes where the drain pads are configured to provide an output from a fourth die side, where the fourth die side is connected to the first die side and the second die side. The process further includes where the drain pads are configured to provide an output from a third die side, where the third die side is connected to the first die side and the second die side; and where the drain pads are configured to provide an output from a fourth die side, where the fourth die side is connected to the first die side and the second die side. The process in addition includes where the gate pad is configured to extend longitudinally along the transistor die; and where the drain pads are configured to extend laterally across the transistor die. The process moreover includes where the drain pads are configured to extend laterally across the transistor die; and where the gate pad is configured to extend laterally across the transistor die between the drain pads. The process also includes where the gate pad is arranged on an axis at least semi-orthogonally to an axis of the implementations of the drain pads. The process further includes where the gate pad is arranged on an axis at least orthogonally to an axis of the implementations of the drain pads. The process in addition includes where an output from the transistor die from the drain pads is arranged on an axis at least semi-orthogonally to an axis of an input to the gate pad. The process moreover includes where the transistor die is configured as a flip chip. The process also includes may include: arranging a drain pad connection on the drain pads, where the drain pad connection is a pillar; and arranging a source connection on the source fingers, where the source connection is a pillar. The process further includes may include arranging a second harmonic control capacitor on the transistor die, where the second harmonic control capacitor may include a second harmonic circuit connection; and where the second harmonic circuit connection connects the second harmonic control capacitor and/or the source fingers to a device. The process in addition includes where the second harmonic circuit connection may include a pillar. The process moreover includes where the second harmonic control capacitor is implemented with a metal insulator metal (MIM) configuration arranged on the transistor die. The process also includes may include arranging an output capacitor on the transistor die and configured as an output series capacitor. The process further includes where the output capacitor connects to an implementation of the drain pads. The process in addition includes where the output capacitor may include a capacitor connection to a device. The process moreover includes where the capacitor connection may include a pillar. The process also includes where the output capacitor is implemented with a metal insulator metal (MIM) configuration arranged on the transistor die. The process further includes and may include implementing an integrated passive device (IPD). The process in addition includes where the device implements a second harmonic circuit implemented in part on the transistor die and in part on the integrated passive device (IPD). The process moreover includes where the second harmonic circuit connects to a second harmonic control capacitor arranged on the transistor die. The process also includes where the second harmonic circuit may include an inductor connected to the second harmonic control capacitor by a second harmonic circuit connection; and where the inductor is implemented on the integrated passive device (IPD). The process further includes may include implementing a shunt L circuit at least in part on the device and connected to the drain pads by a drain pad connection. The process in addition includes where the shunt L circuit may include an inductor and a capacitor. The process moreover includes where the shunt L circuit is configured to receive a direct current (DC) feed. The process also includes may include implementing a baseband termination circuit that may include a resistor and a capacitor implemented on the integrated passive device (IPD). The process further includes may include implementing a wide band application circuit that may include an output capacitor arranged on the transistor die. The process in addition includes may include: configuring an input to form an RF input for the device and the input being connected to the gate pad; and configuring an output to form an RF output for the device and the output being connected to the drain pads; and where the output is configured on an axis at least semi-orthogonally to an axis of the input. The process moreover includes may include configuring a capacitor as part of F0 high pass capacitor circuit connected to the source fingers. The process also includes where the capacitor is implemented with a metal insulator metal (MIM) configuration arranged on the transistor die. The process further includes where the transistor die may include two separate transistor devices combined. The process in addition includes where the transistor die may include two separate discrete transistor devices. The process moreover includes may include implementing a second transistor, where the transistor and the second transistor may include two separate discrete devices configured in a Doherty implementation.

Accordingly, the disclosure has provided a transistor with a gate layout, a device implementing the transistor with output pre-matching, a process of implementing the transistor, and a process of implementing the device each having improved broadband and efficiency.

The adhesive of the disclosure may be utilized in an adhesive bonding process that may include applying an intermediate layer to connect surfaces to be connected. The adhesive may be organic or inorganic; and the adhesive may be deposited on one or both surfaces of the surface to be connected. The adhesive may be utilized in an adhesive bonding process that may include applying adhesive material with a particular coating thickness, at a particular bonding temperature, for a particular processing time while in an environment that may include applying a particular tool pressure. In one aspect, the adhesive may be a conductive adhesive, an epoxy-based adhesive, a conductive epoxy-based adhesive, and/or the like.

The solder of the disclosure may be utilized to form a solder interface that may include solder and/or be formed from solder. The solder may be any fusible metal alloy that may be used to form a bond between surfaces to be connected. The solder may be a lead-free solder, a lead solder, a eutectic solder, or the like. The lead-free solder may contain tin, copper, silver, bismuth, indium, zinc, antimony, traces of other metals, and/or the like. The lead solder may contain lead, other metals such as tin, silver, and/or the like. The solder may further include flux as needed.

The sintering of the disclosure may utilize a process of compacting and forming a conductive mass of material by heat and/or pressure. The sintering process may operate without melting the material to the point of liquefaction. The sintering process may include sintering of metallic nano or hybrid powders in pastes or epoxies. The sintering process may include sintering in a vacuum. The sintering process may include sintering with the use of a protective gas.

The eutectic bonding of the disclosure may utilize a eutectic soldering process that may form a eutectic system. The eutectic system may be used between surfaces to be connected. The eutectic bonding may utilize metals that may be alloys and/or intermetallics that transition from solid to liquid state, or from liquid to solid state, at a specific composition and temperature. The eutectic alloys may be deposited by sputtering, evaporation, electroplating, and/or the like.

The ultrasonically welding of the disclosure may utilize a process whereby high-frequency ultrasonic acoustic vibrations are locally applied to components being held together under pressure. The ultrasonically welding may create a solid-state weld between surfaces to be connected. In one aspect, the ultrasonically welding may include applying a sonicated force.

As may be appreciated by those skilled in the art, the illustrated structure is a logical structure and not a physical one. Accordingly, the illustrated modules can be implemented by employing various hardware and software components. In addition, two or more of the logical components can be implemented as a single module that provides functionality for both components. In one aspect, the components are implemented as software program modules.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The many features and advantages of the disclosure are apparent from the detailed specification, and, thus, it is intended by the appended claims to cover all such features and advantages of the disclosure which fall within the true spirit and scope of the disclosure. Further, since numerous modifications and variations will readily occur to those skilled in the art, it is not desired to limit the disclosure to the exact construction and operation illustrated and described, and, accordingly, all suitable modifications and equivalents may be resorted to that fall within the scope of the disclosure.

1. A transistor die comprising:
at least one drain pad arranged at a first die side of the transistor die and/or at a second die side of the transistor die, the first die side and the second die side being opposed sides of the transistor die;
drain fingers configured to extend from the at least one drain pad longitudinally toward a central location of the transistor die;
source fingers configured to extend from the at least one drain pad longitudinally toward the central location of the transistor die; and
a gate pad and a gate and the gate is configured to extend along implementations of the drain fingers and/or the source fingers,
wherein the gate pad is arranged on an axis at least semi-orthogonally to an axis of the at least one drain pad.

2. The transistor die according to claim 1 wherein an output from the transistor die from the at least one drain pad is arranged on an axis at least semi-orthogonally to an axis of an input to the gate pad.

3. The transistor die according to claim 1
wherein the at least one drain pad comprise a dimension extending laterally across the transistor die greater than a dimension longitudinally along the transistor die; and
wherein the gate pad comprises a dimension longitudinally along the transistor die greater than a dimension extending laterally across the transistor die.

4. The transistor die according to claim 1
wherein a longer dimension of the gate pad extends longitudinally along the transistor die; and
wherein a longer dimension of the at least one drain pad extends laterally across the transistor die.

5. The transistor die according to claim 1
wherein the drain fingers comprise multiple parallel implementations extending laterally across the transistor die; and
wherein the source fingers comprise multiple parallel implementations extending laterally across the transistor die.

6. The transistor die according to claim 1
wherein the drain fingers comprises a dimension longitudinally along the transistor die greater than a dimension extending laterally across the transistor die; and
wherein the source fingers have a dimension longitudinally along the transistor die greater than a dimension extending laterally across the transistor die.

7. The transistor die according to claim 1 wherein the at least one drain pad are configured to provide an output from a third die side, wherein the third die side is connected to the first die side and the second die side.

8. The transistor die according to claim 1 wherein the at least one drain pad are configured to provide an output from a fourth die side, wherein the fourth die side is connected to the first die side and the second die side.

9. The transistor die according to claim 1
wherein the gate pad is configured to extend longitudinally along the transistor die; and
wherein the at least one drain pad are configured to extend laterally across the transistor die.

10. The transistor die according to claim 1
wherein the at least one drain pad comprises drain pads; and
wherein the drain fingers and the source fingers are arranged between the drain pads.

11-14. (canceled)

15. The transistor die according to claim 1 wherein the transistor die is configured as a flip chip.

16. (canceled)

17. The transistor die according to claim 1 further comprising a second harmonic control capacitor arranged on the transistor die,
wherein the second harmonic control capacitor comprises a second harmonic circuit connection; and
wherein the second harmonic circuit connection connects the second harmonic control capacitor and/or the source fingers to a device.

18. The transistor die according to claim 17 wherein the second harmonic circuit connection comprises a pillar.

19. The transistor die according to claim 17 wherein the second harmonic control capacitor is implemented with a metal insulator metal (MIM) configuration arranged on the transistor die.

20. The transistor die according to claim 1 further comprising an output capacitor arranged on the transistor die and configured as an output series capacitor.

21. The transistor die according to claim 20 wherein the output capacitor connects to an implementation of the at least one drain pad.

22. The transistor die according to claim 20 wherein the output capacitor comprises a capacitor connection to a device.

23. The transistor die according to claim 22 wherein the capacitor connection comprises a pillar.

24. The transistor die according to claim 20 wherein the output capacitor is implemented with a metal insulator metal (MIM) configuration arranged on the transistor die.

25. A device comprising the transistor die according to claim 1 and further comprising an integrated passive device (IPD).

26-28. (canceled)

29. The device according to claim 25 further comprising a shunt L circuit implemented at least in part on the device and connected to the at least one drain pad by a drain pad connection.

30-32. (canceled)

33. The device according to claim 25 further comprising a wide band application circuit that comprises an output capacitor arranged on the transistor die.

34. The device according to claim 25 further comprising:
an input configured to form an RF input for the device and the input being connected to the gate pad; and
an output configured to form an RF output for the device and the output being connected to the at least one drain pad; and
wherein the output is configured on an axis at least semi-orthogonally to an axis of the input.

35. The device according to claim 25 further comprising a capacitor configured as part of F0 high pass capacitor circuit connected to the source fingers.

36. (canceled)

37. The device according to claim 25 wherein the transistor die comprises two separate transistor devices combined.

38. The device according to claim 25 wherein the transistor die comprises two separate discrete transistor devices.

39. The device according to claim 25 further comprising a second transistor, wherein the transistor and the second transistor comprise two separate discrete devices configured in a Doherty implementation.

40. A transistor die comprising:
drain pads arranged at a first die side of the transistor die and at a second die side of the transistor die, the first die side and the second die side being opposed sides of the transistor die;
drain fingers arranged at the first die side of the transistor die and the second die side of the transistor die;
source fingers arranged at the first die side of the transistor die and a second die side of the transistor die; and
a gate pad and a gate and the gate configured to extend along implementations of the drain fingers and/or the source fingers on the first die side and implementations of the drain fingers and/or the source fingers on the second die side.

41-81. (canceled)

82. A process of implementing a transistor die comprising:
arranging at least one drain pad at a first die side of the transistor die and/or at a second die side of the transistor die, the first die side and the second die side being opposed sides of the transistor die;
configuring drain fingers to extend from the at least one drain pad longitudinally toward a central location of the transistor die;
configuring source fingers to extend from the at least one drain pad longitudinally toward the central location of the transistor die;
arranging a gate pad on an axis at least semi-orthogonally to an axis of the at least one drain pad; and
configuring a gate to extend along implementations of the drain fingers and/or the source fingers.

83-162. (canceled)
